(19) United States
(12) Patent Application Publication
(10) Pub. No.: US 2023/0307473 A1
(43) Pub. Date: Sep. 28, 2023

(54) LIGHT RECEIVING ELEMENT, MANUFACTURING METHOD FOR SAME, AND ELECTRONIC DEVICE

(71) Applicant: SONY SEMICONDUCTOR SOLUTIONS CORPORATION, Kanagawa (JP)

(72) Inventor: Masataka SATO, Kanagawa (JP)

(73) Assignee: SONY SEMICONDUCTOR SOLUTIONS CORPORATION, Kanagawa (JP)

(21) Appl. No.: 18/004,773

(22) PCT Filed: Jul. 2, 2021
(86) PCT No.: PCT/JP2021/025083

§ 371 Date: Jan. 9, 2023

(30) Foreign Application Priority Data
Jul. 17, 2020 (JP) 2020-122780

(51) Int. Cl. H01L 27/146

(52) U.S. Cl. CPC H01L 27/14612; H01L 27/14634; H01L 27/14645; H01L 27/1465; H01L 27/1469; G01S 7/4816

(57) ABSTRACT

The present technology relates to a light receiving element, a manufacturing method of same, and an electronic device that enables enhancement of quantum efficiency with respect to infrared light and an improvement in sensitivity. The light receiving element includes a pixel array region in which pixels including photoelectric conversion regions are aligned in a matrix shape, and the photoelectric conversion region of each pixel on a first semiconductor substrate, on which the pixel array region is formed, is formed of an SiGe region or a Ge region. The present technology can be applied to, for example, a distance measurement module for measuring a distance to an object, and the like.

### TECHNICAL FIELD

The present technology relates to a light receiving element, a manufacturing method for same, and an electronic device, and particularly to a light receiving element, a manufacturing method for same, and an electronic device capable of enhancing quantum efficiency with respect to infrared light and improving sensitivity.

### BACKGROUND ART

A distance measurement module using an indirect time-of-flight (ToF) scheme is known. In the distance measurement module of the indirect ToF scheme, irradiation light is emitted toward an object, and a light receiving element receives reflected light of the irradiation light reflected by and returning from a surface of the object. The light receiving element splits signal charges obtained by photoelectrically converting the reflected light into two charge accumulation regions, for example, and calculates the distance from a distribution ratio of the signal charges. Such a light receiving element with a light receiving property enhanced by employing a rear surface irradiation type has been proposed (see PTL 1, for example).

### CITATION LIST

### Patent Literature

[PTL 1] WO 2018/135320

### SUMMARY

### Technical Problem

As irradiation light for the distance measurement module, light in the near-infrared region is typically used. Quantum efficiency (QE) of the light in the near-infrared region is low in a case where a silicon substrate is used as a semiconductor substrate for the light receiving element, and this leads to degradation of sensor sensitivity.

The present technology was made in view of such circumstances and is intended to enable enhancement of quantum efficiency with respect to infrared light and an improvement in sensitivity.

### Solution to Problem

A light receiving element according to a first aspect of the present technology includes: a pixel array region in which pixels including photoelectric conversion regions are aligned in a matrix shape, and the photoelectric conversion region of each pixel on a first semiconductor substrate, on which the pixel array region is formed, is formed of a SiGe region or a Ge region.

A manufacturing method for a light receiving element according to a second aspect of the present technology includes: forming at least a photoelectric conversion region of each pixel in a pixel array region on a semiconductor substrate by an SiGe region or a Ge region.

An electronic device according to a third aspect of the present technology includes: a light receiving element that includes a pixel array region in which pixels including photoelectric conversion regions are aligned in a matrix shape, in which the photoelectric conversion region of each pixel on a first semiconductor substrate, on which the pixel array region is formed, is formed of an SiGe region or a Ge region.

In the first to third aspects of the present technology, at least the photoelectric conversion region of each pixel in the pixel array region on the semiconductor substrate is formed of the SiGe region or the Ge region.

The light receiving element and the electronic device may be independent devices or may be modules incorporated in other devices.

### BRIEF DESCRIPTION OF DRAWINGS

[FIG. 1]

FIG. 1 is a block diagram illustrating a schematic configuration example of a light receiving element to which the present technology is applied.

[FIG. 2] FIG. 2 is a sectional view illustrating a first configuration example of pixels.

[FIG. 3] FIG. 3 is a diagram illustrating a circuit configuration of a pixel.

[FIG. 4] FIG. 4 is a plan view illustrating an example of arrangement of the pixel circuit in FIG. 3.

[FIG. 5] FIG. 5 is a diagram illustrating another circuit configuration example of the pixel.

[FIG. 6] FIG. 6 is a plan view illustrating an example of arrangement of the pixel circuit in FIG. 5.

[FIG. 7] FIG. 7 is a plan view illustrating arrangement of pixels in a pixel array portion.

[FIG. 8] FIG. 8 is a diagram for explaining a first formation method of an SiGe region.

[FIG. 9] FIG. 9 is a diagram for explaining a second formation method of the SiGe region.

[FIG. 10] FIG. 10 is a plan view illustrating another formation example of the SiGe region in a pixel.

[FIG. 11] FIG. 11 is a diagram for explaining a formation method of the pixel in FIG. 10.

[FIG. 12] FIG. 12 is a schematic perspective view illustrating a substrate configuration example of the light receiving element.

[FIG. 13] FIG. 13 is a sectional view of pixels in a case of a configuration of a laminated structure of two substrates.

[FIG. 14] FIG. 14 is a schematic sectional view of the light receiving element formed by laminating three semiconductor substrates.

[FIG. 15] FIG. 15 is a plan view of a pixel in a case of a 4-tap pixel structure.

[FIG. 16] FIG. 16 is a diagram illustrating another formation example of the SiGe region.

[FIG. 17] FIG. 17 is a diagram illustrating another formation example of the SiGe region.

[FIG. 18] FIG. 18 is a sectional view illustrating an example of Ge concentration.

[FIG. 19] FIG. 19 is a block diagram illustrating a detailed configuration example of a pixel including an AD conversion portion for each pixel.

[FIG. 20] FIG. 20 is a circuit diagram illustrating detailed configurations of a comparison circuit and a pixel circuit.

[FIG. 21] FIG. 21 is a circuit diagram illustrating connection between an output of each tap of the pixel circuit and the comparison circuit.

[FIG. 22] FIG. 22 is a sectional view illustrating a second configuration example of pixels.

[FIG. 23] FIG. 23 is a sectional view illustrating the vicinity of a pixel transistor in FIG. 22 in an enlarged manner.

[FIG. 24] FIG. 24 is a sectional view illustrating a third configuration example of pixels.

[FIG. 25] FIG. 25 is a diagram illustrating a circuit configuration of a pixel in a case of an IR imaging sensor.

[FIG. 26] FIG. 26 is a sectional view of the pixel in the case of the IR imaging sensor.

[FIG. 27] FIG. 27 is a diagram illustrating an example of arrangement of pixels in a case of an RGBIR imaging sensor.

[FIG. 28] FIG. 28 is a sectional view illustrating an example of a color filter layer in the case of the RGBIR imaging sensor.

[FIG. 29] FIG. 29 is a diagram illustrating a circuit configuration example of an SPAD pixel.

[FIG. 30] FIG. 30 is a diagram for explaining operations of the SPAD pixel in FIG. 29.

[FIG. 31] FIG. 31 is a sectional view illustrating a configuration example of the case of the SPAD pixel.

[FIG. 32] FIG. 32 is a diagram illustrating a circuit configuration example in a case of a CAPD pixel.

[FIG. 33] FIG. 33 is a sectional view illustrating a configuration example of the CAPD pixel.

[FIG. 34] FIG. 34 is a block diagram illustrating a configuration example of a distance measurement module to which the present technology is applied.

[FIG. 35] FIG. 35 is a block diagram illustrating a configuration example of a smartphone as an electronic device to which the present technology is applied.

[FIG. 36] FIG. 36 is a block diagram showing an example of a schematic configuration of a vehicle control system.

[FIG. 37] FIG. 37 is an explanatory diagram showing an example of installation positions of an outside-vehicle information detecting portion and an imaging portion.

### DESCRIPTION OF EMBODIMENTS

Modes for embodying the present technology (hereinafter referred to as embodiments) will be described below with reference to the accompanying drawings. In the present specification and the drawings, components having substantially the same functional configuration will be denoted by the same reference numerals, and thus repeated descriptions thereof will be omitted. The description will be made in the following order.
1. Configuration example of light receiving element
2. Sectional view according to first configuration example of pixel
3. Circuit configuration example of pixel
4. Plan view of pixel
5. Other circuit configuration example of pixel
6. Plan view of pixel
7. Formation method of GeSi region
8. Modification example of first configuration example
9. Substrate configuration example of light receiving element
10. Pixel sectional view in case of laminated structure
11. Three-layer laminated structure
12. Four-tap pixel configuration example
13. Other formation example of SiGe region
14. Detailed configuration example of pixel area ADC
15. Sectional view according to second configuration example of pixel
16. Sectional view according to third configuration example of pixel
17. Configuration example of IR imaging sensor
18. Configuration example of RGBIR imaging sensor
19. Configuration example of SPAD pixel
20. Configuration example of CAPD pixel
21. Configuration example of distance measurement module
22. Configuration example of electronic device
23. Exemplary application to moving body

Note that, in drawings to be referred to hereinafter, same or similar portions are denoted by same or similar reference signs. However, the drawings are schematic and relationships between thicknesses and plan view dimensions, ratios of thicknesses of respective layers, and the like differ from those in real. In addition, drawings include portions where dimensional relationships and ratios differ between the drawings in some cases.

In addition, it is to be understood that definitions of directions such as upward and downward in the following description are merely definitions provided for the sake of brevity and are not intended to limit technical ideas of the present disclosure. For example, when an object is observed after being rotated by 90 degrees, up-down is converted into and interpreted as left-right, and when an object is observed after being rotated by 180 degrees, up-down is interpreted as being inverted.

### 1. Configuration Example of Light Receiving Element

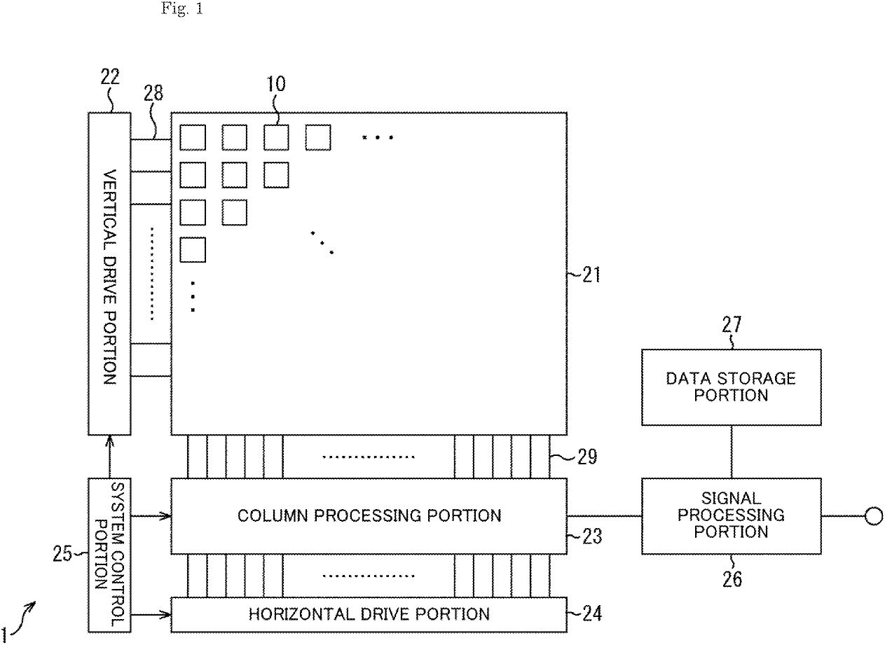

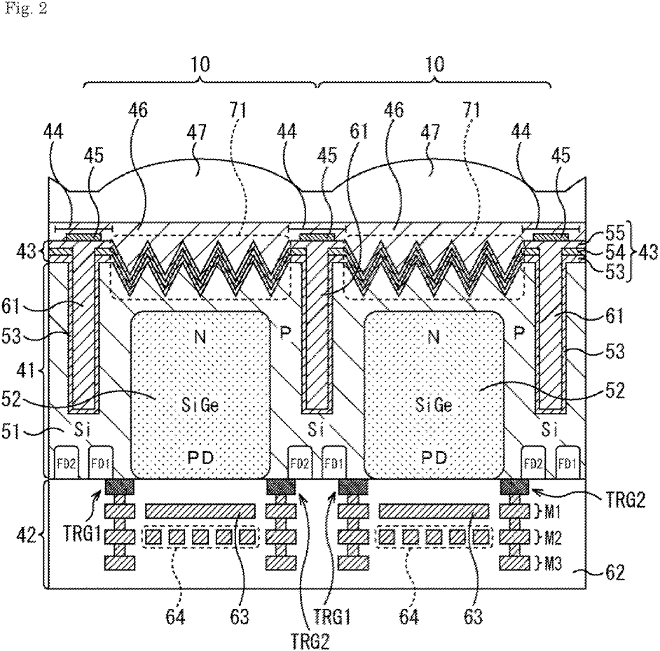

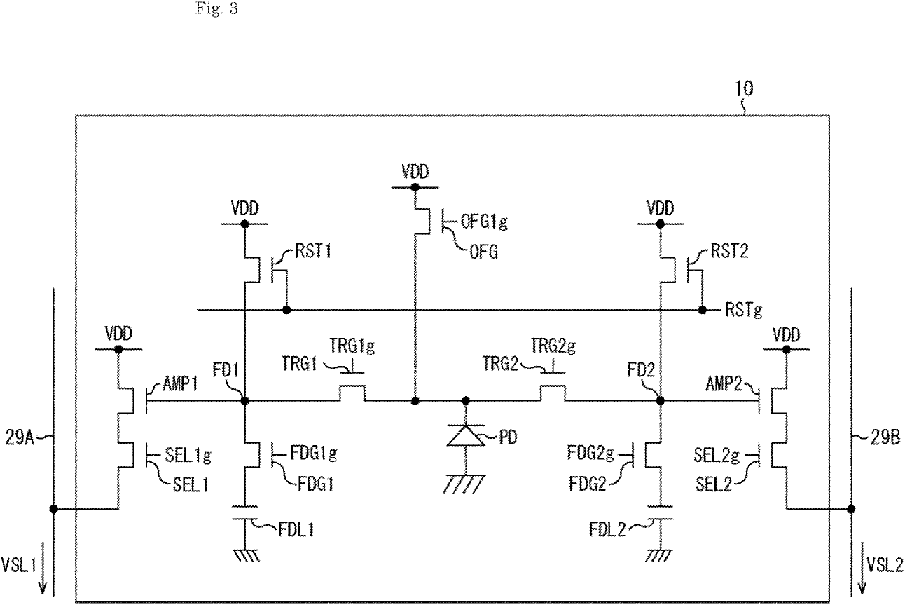

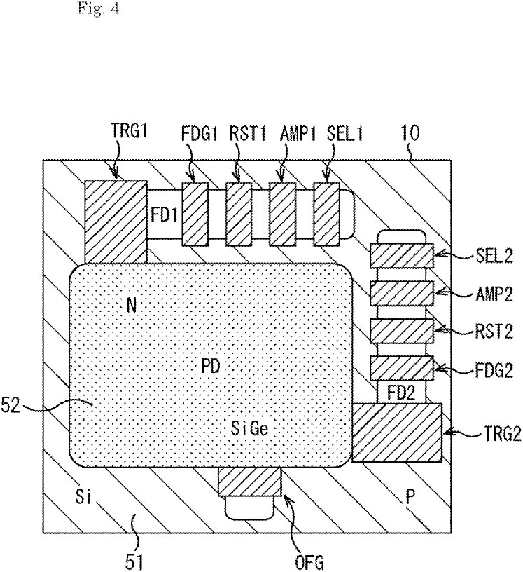

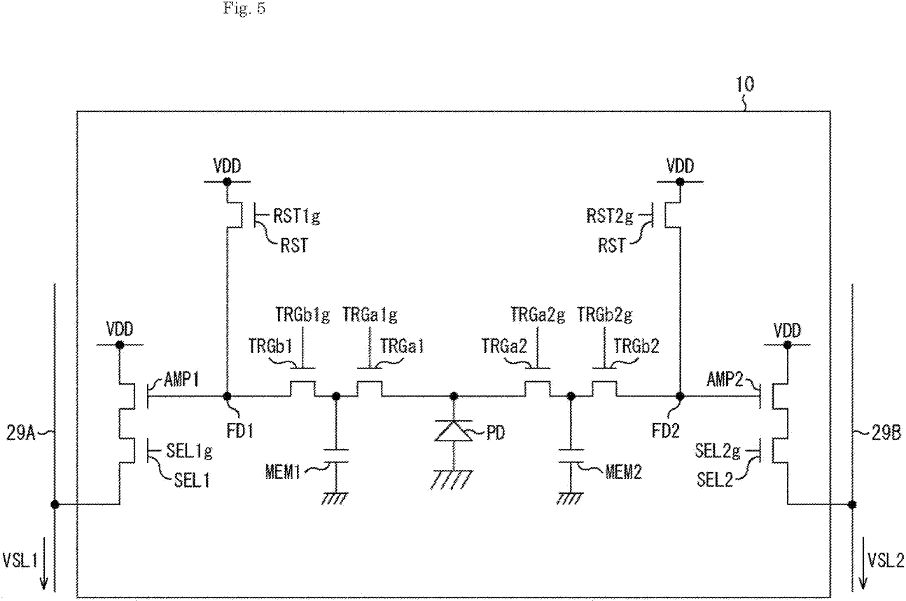

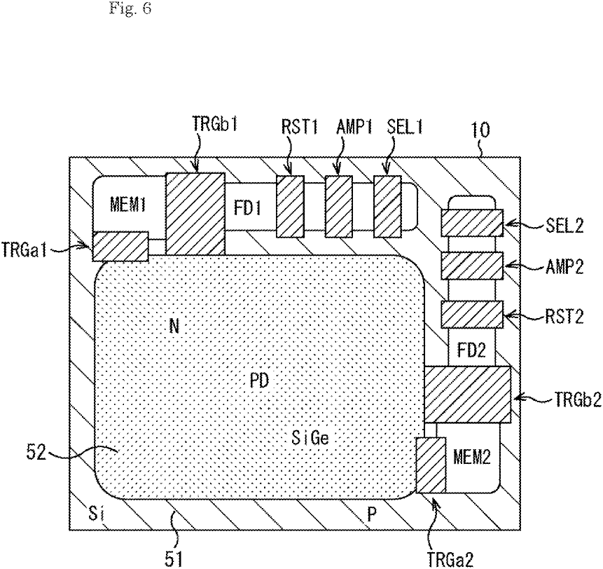

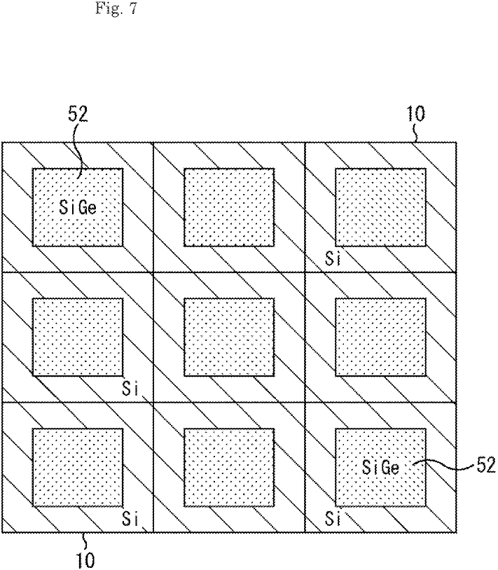

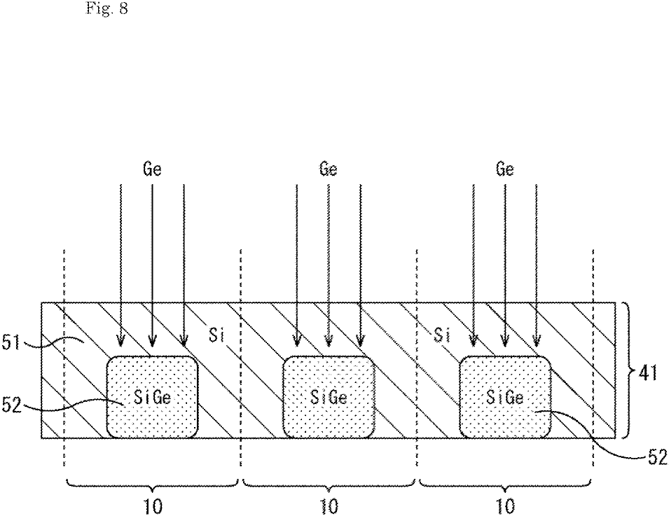

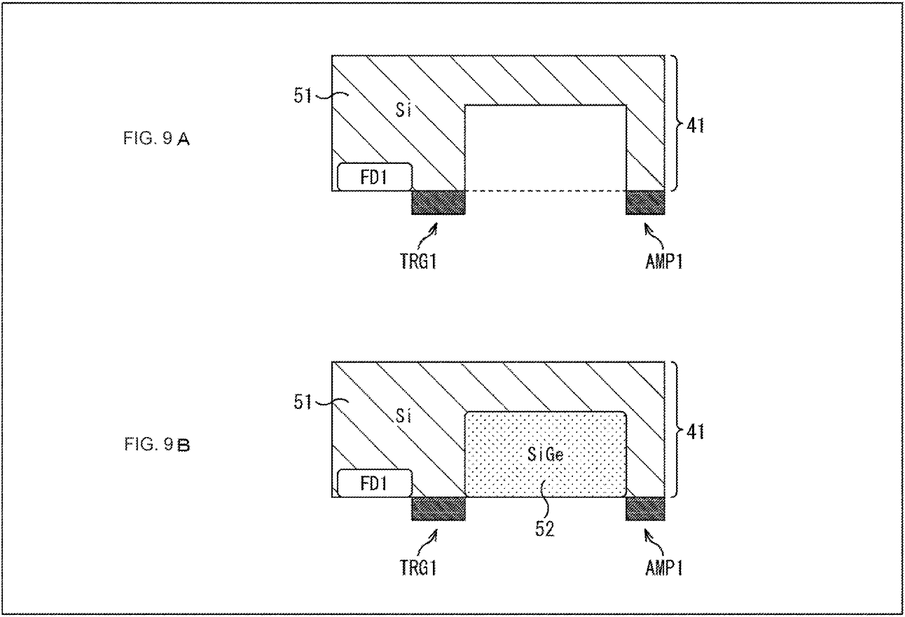

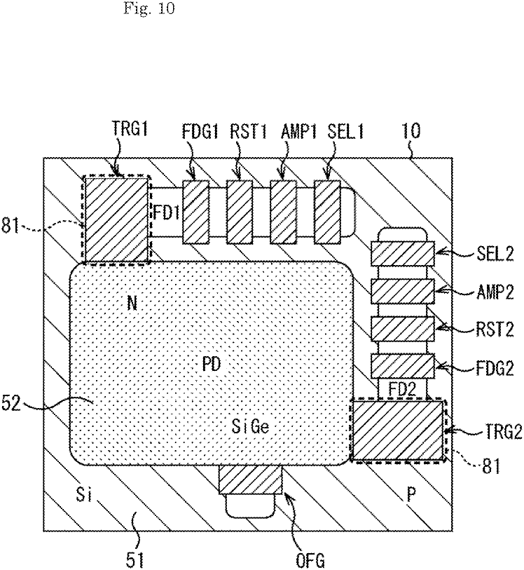

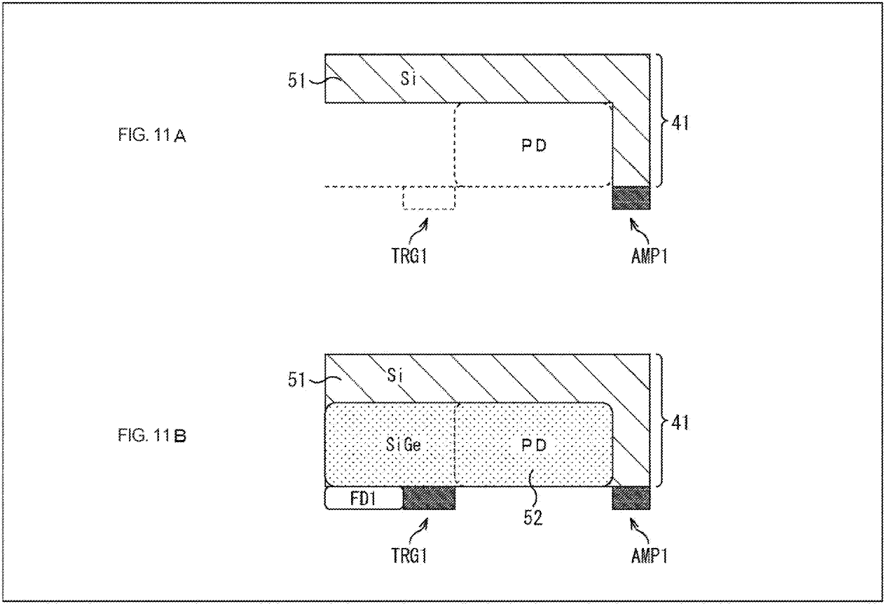

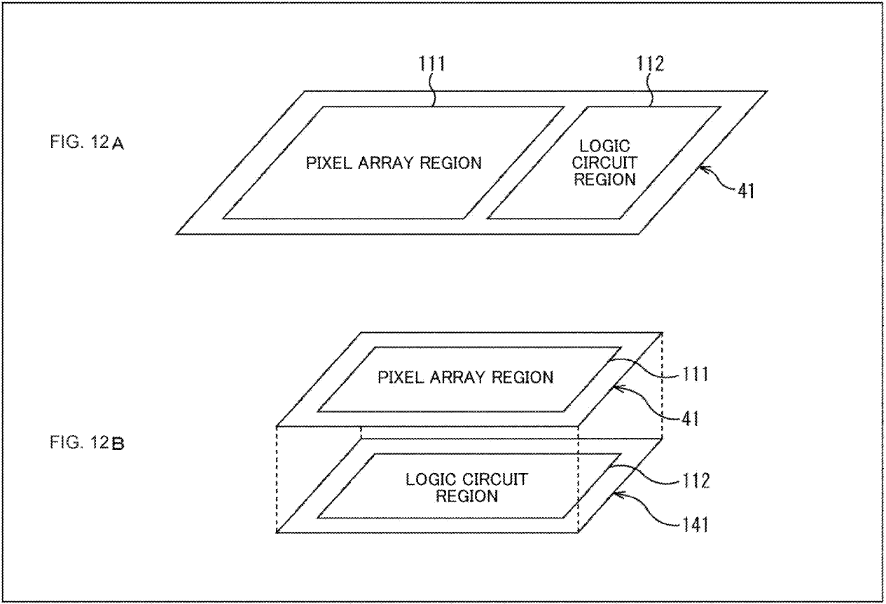

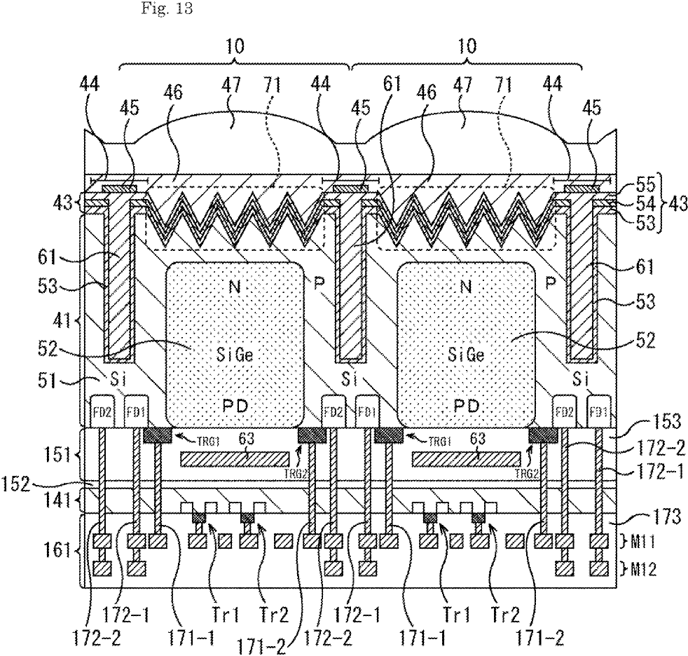

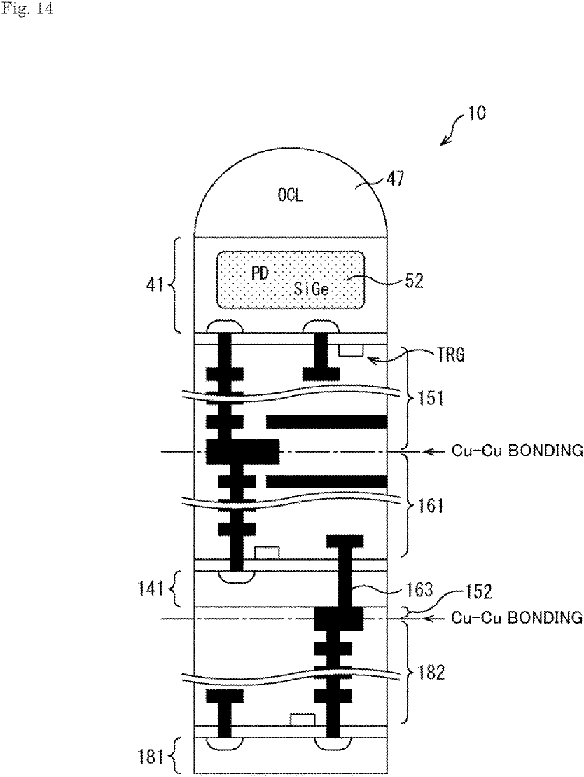

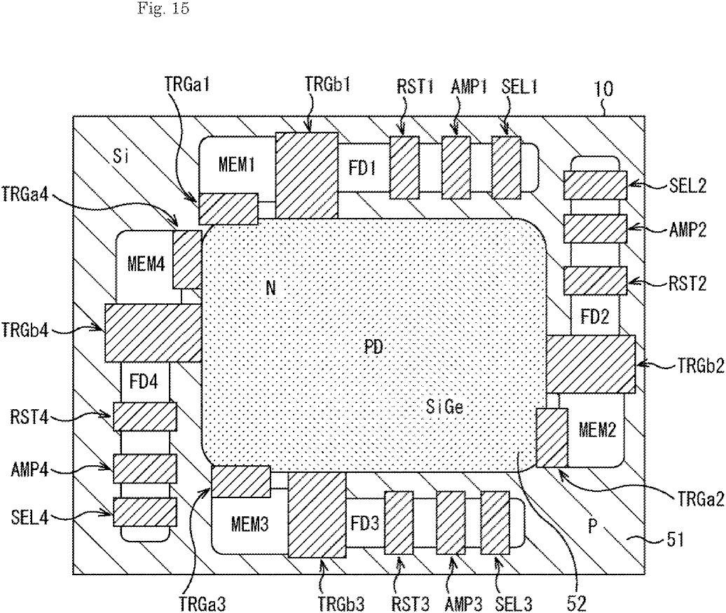

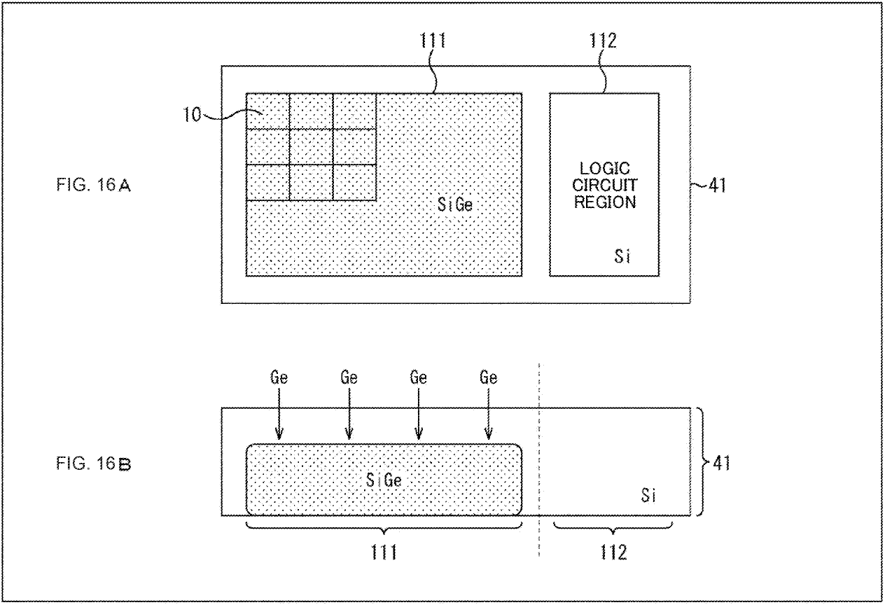

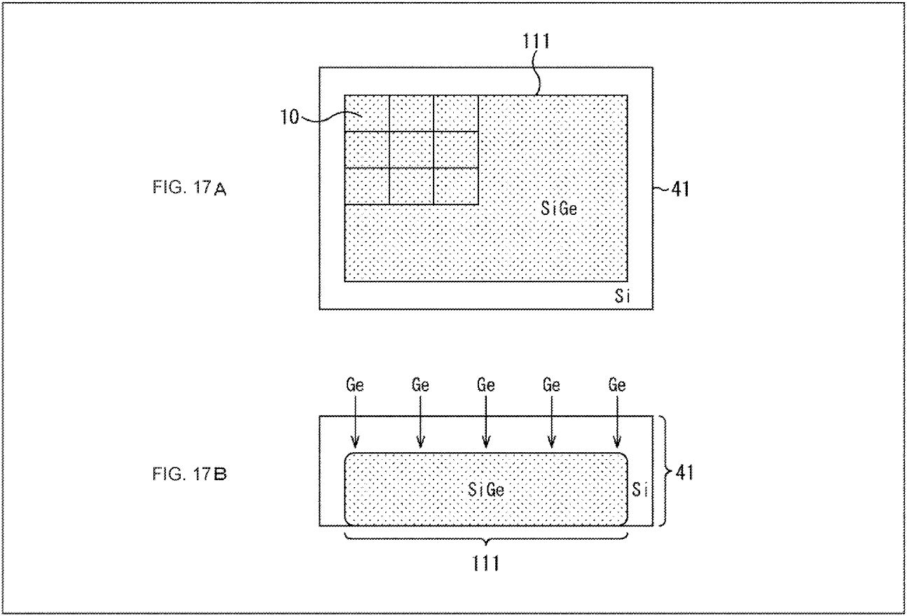

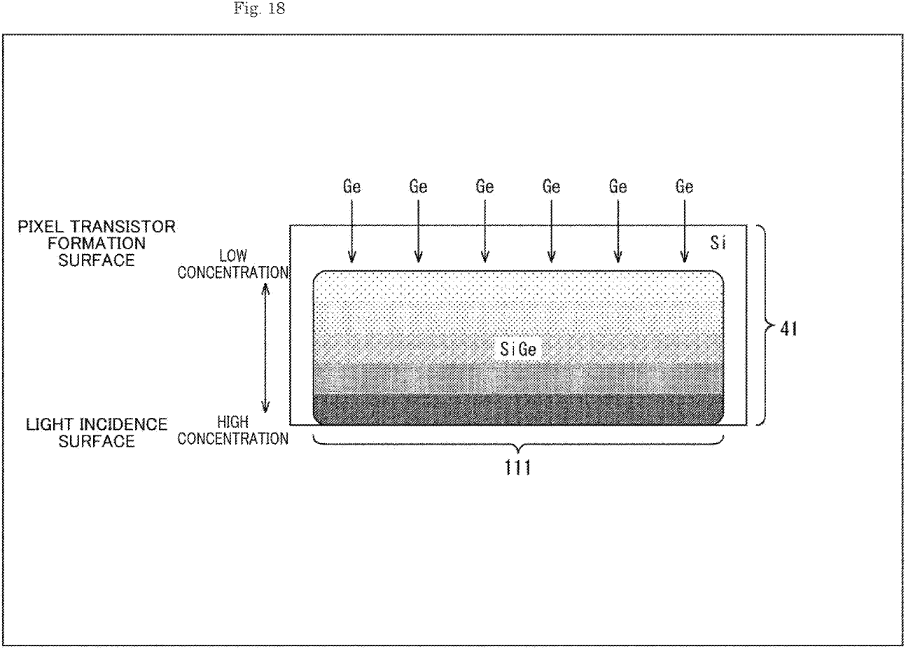

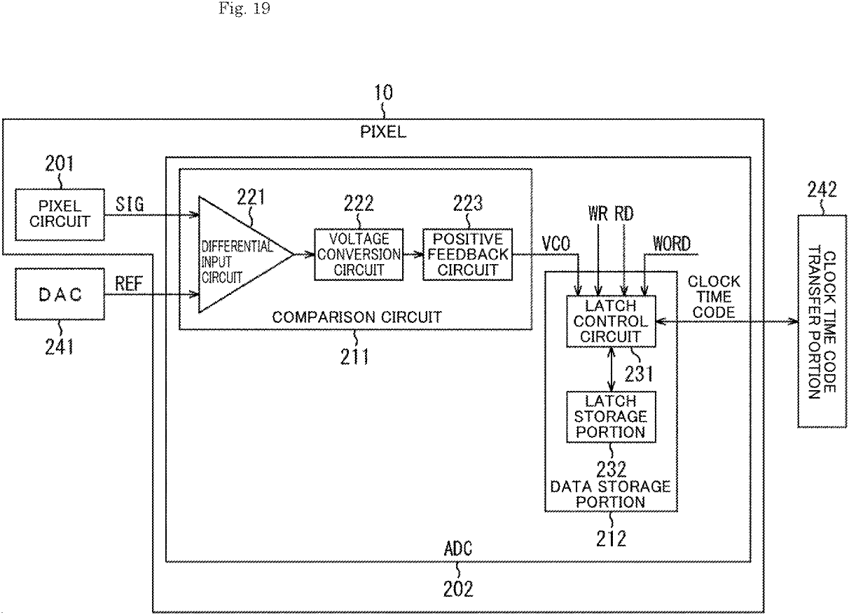

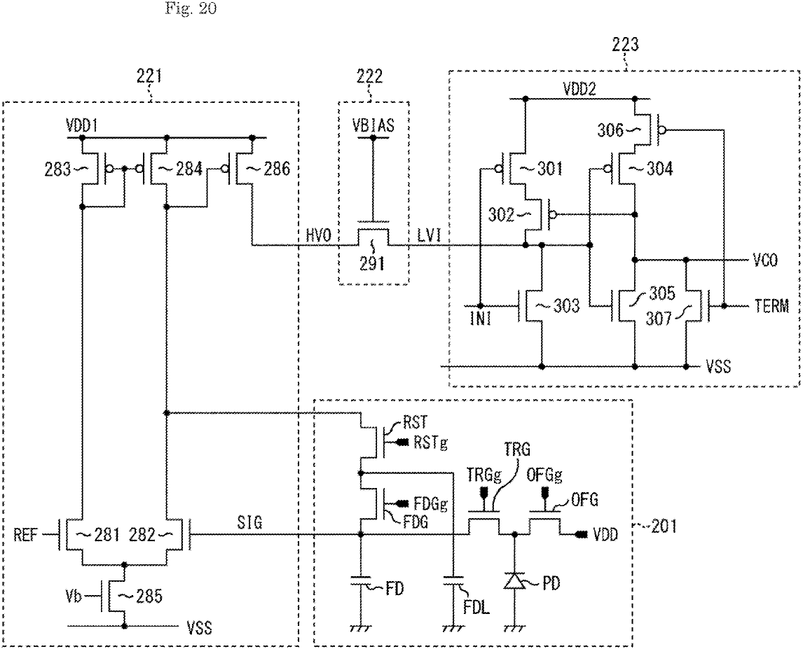

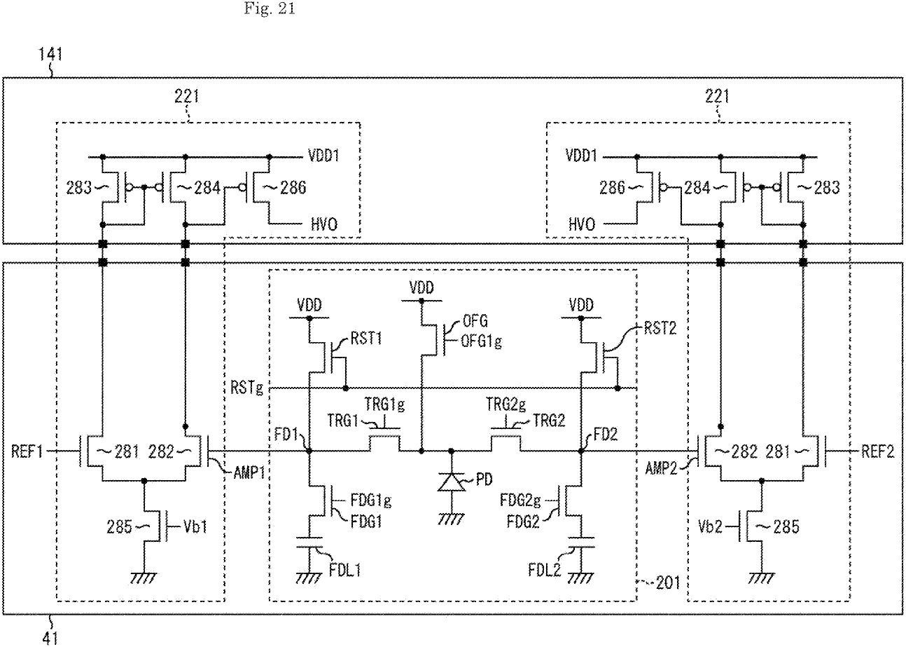

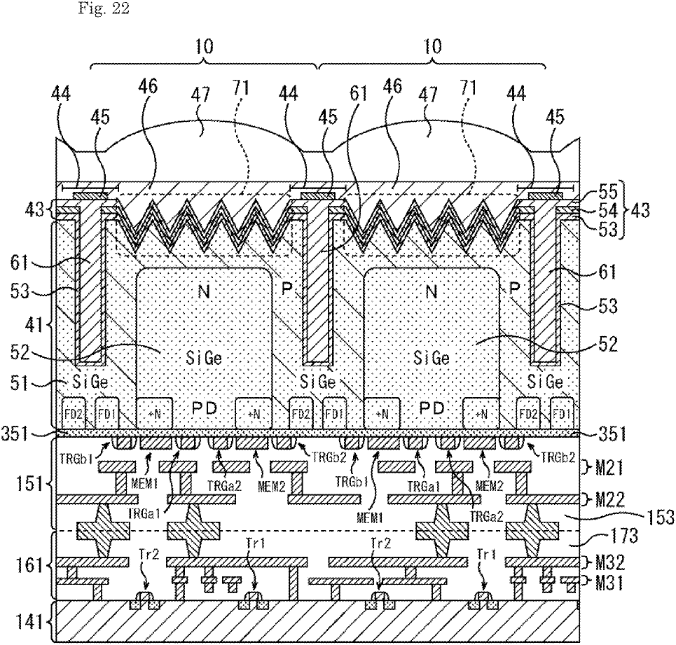

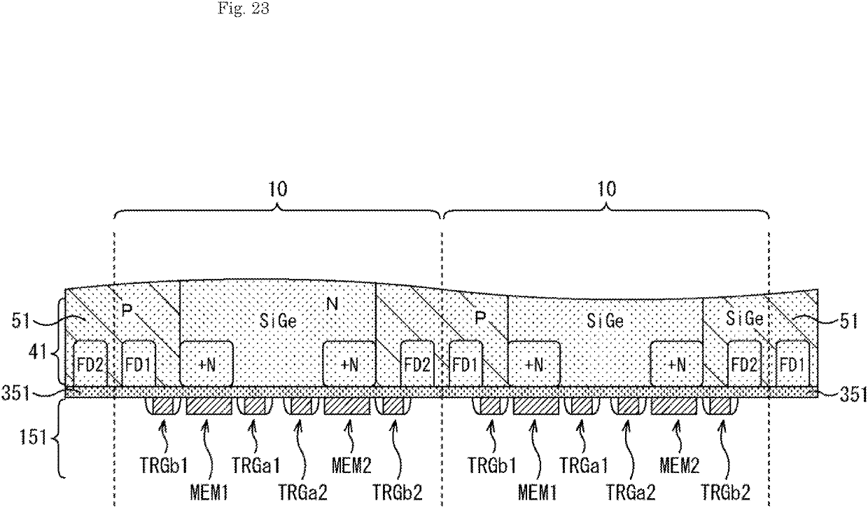

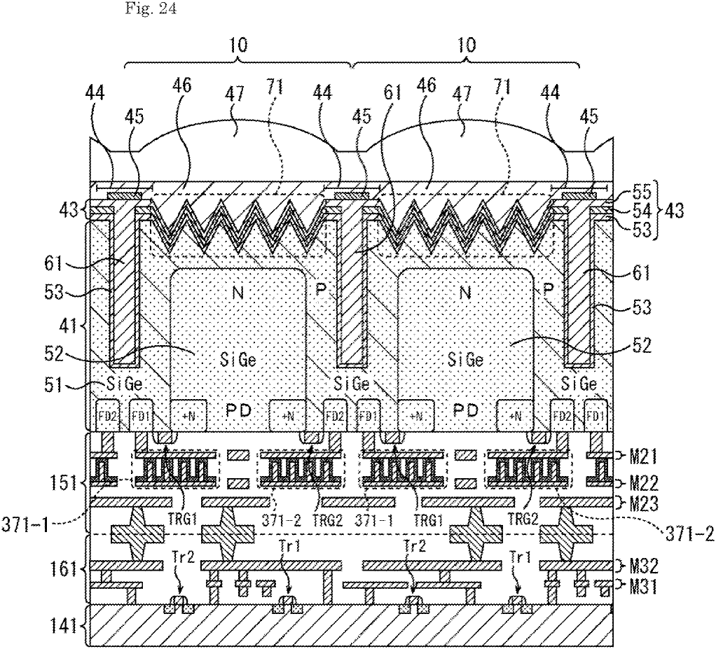

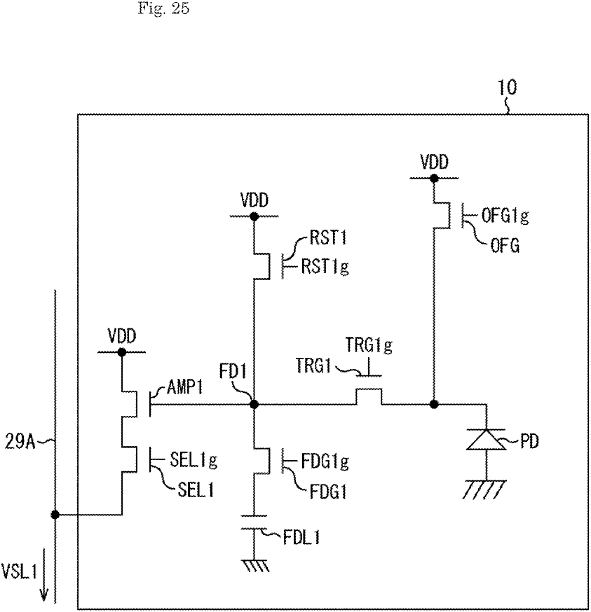

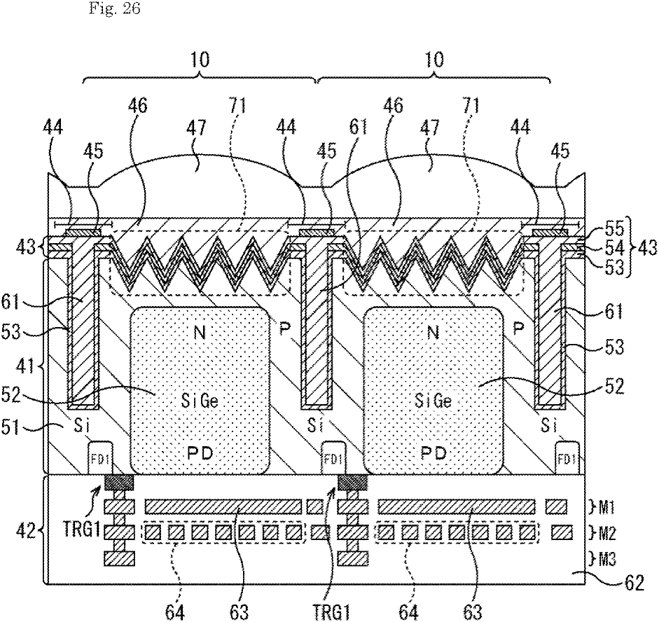

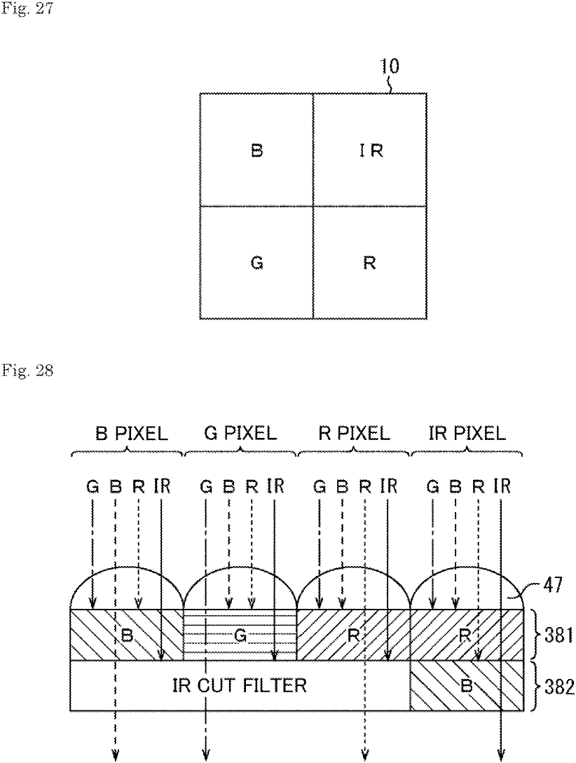

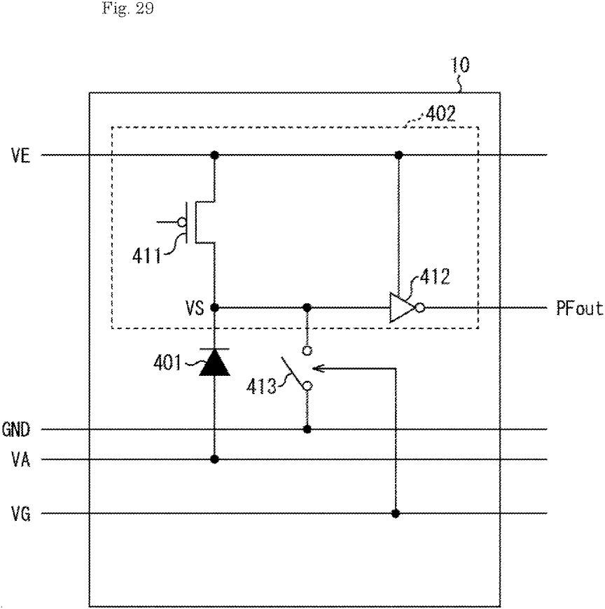

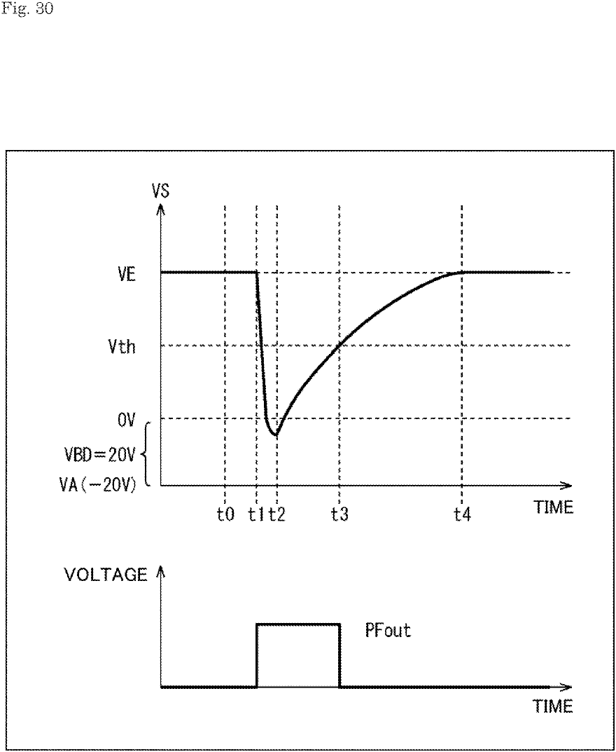

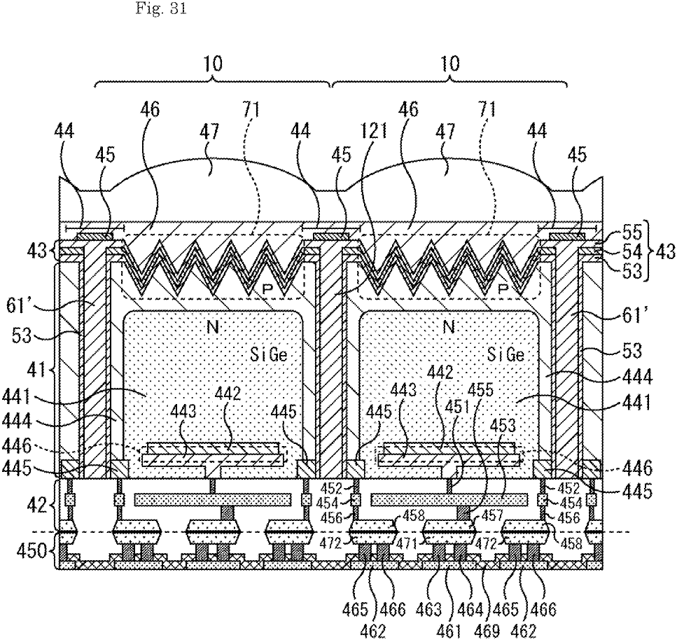

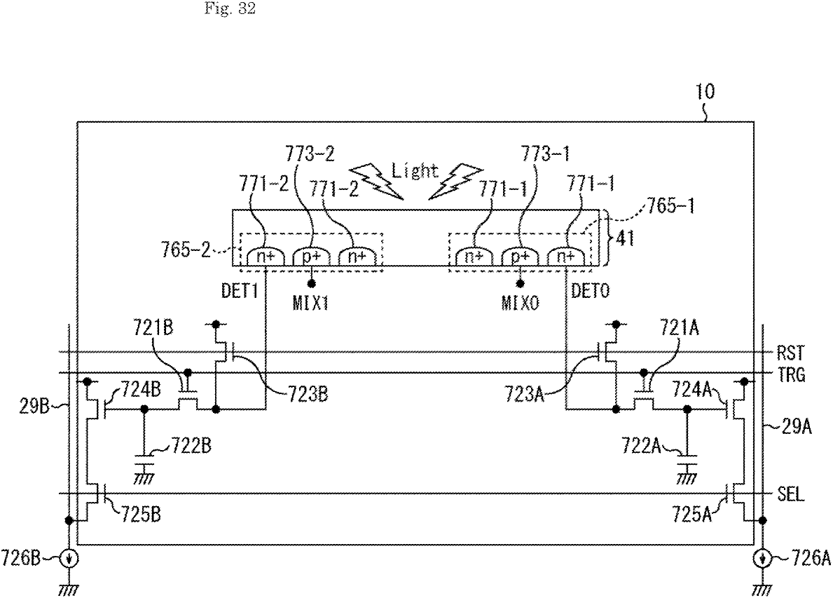

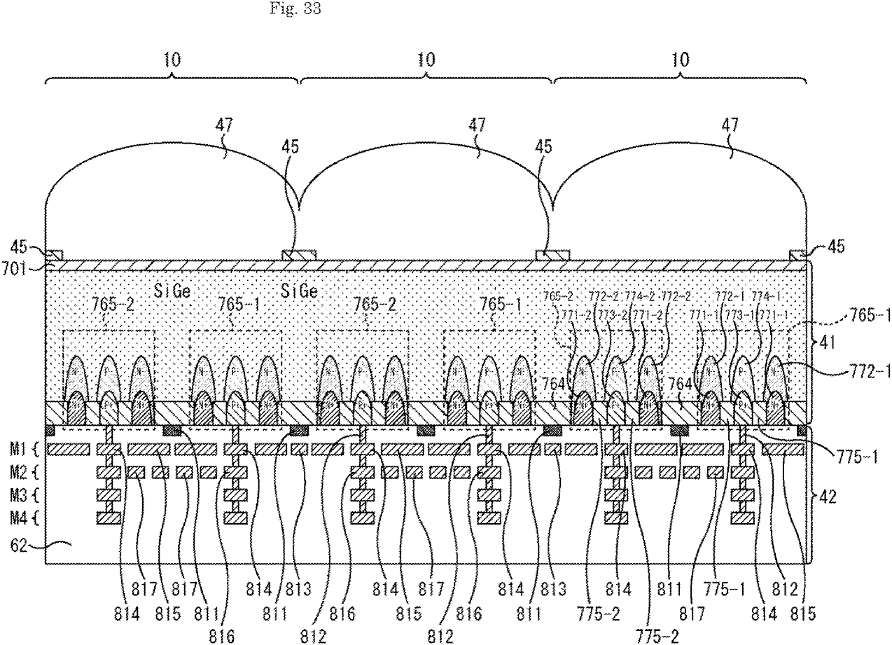

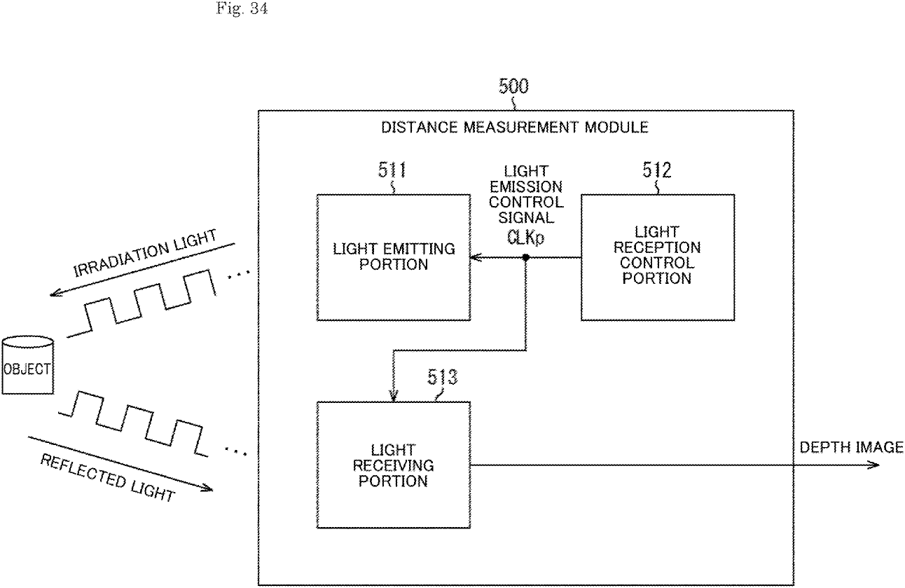

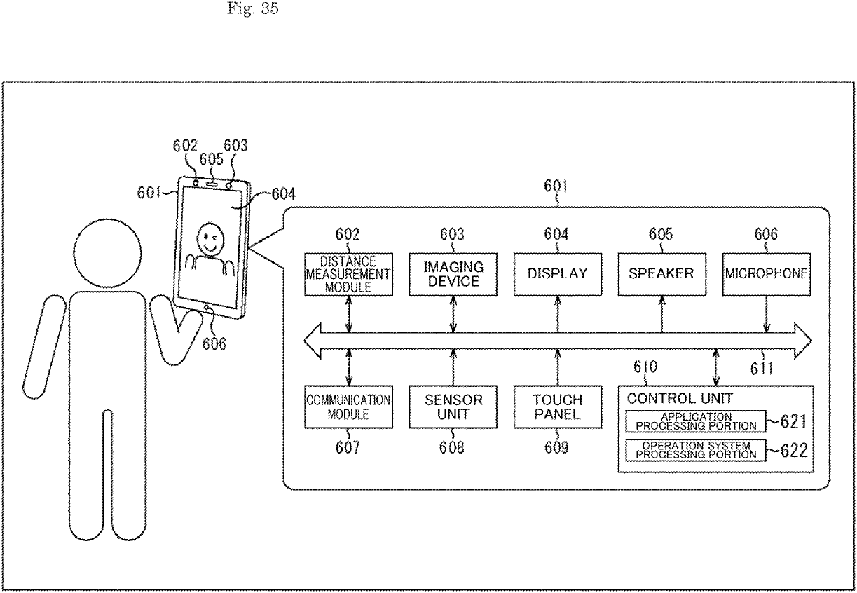

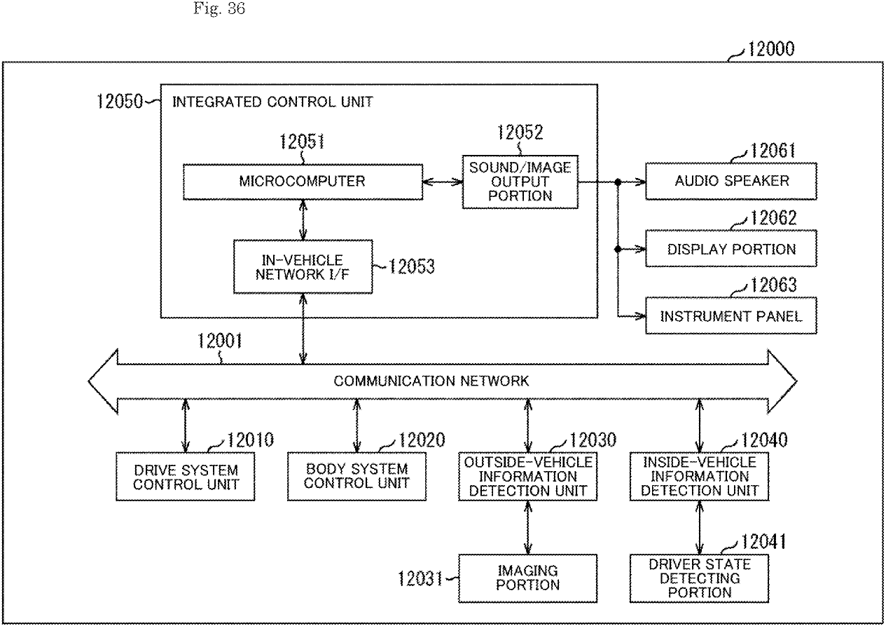

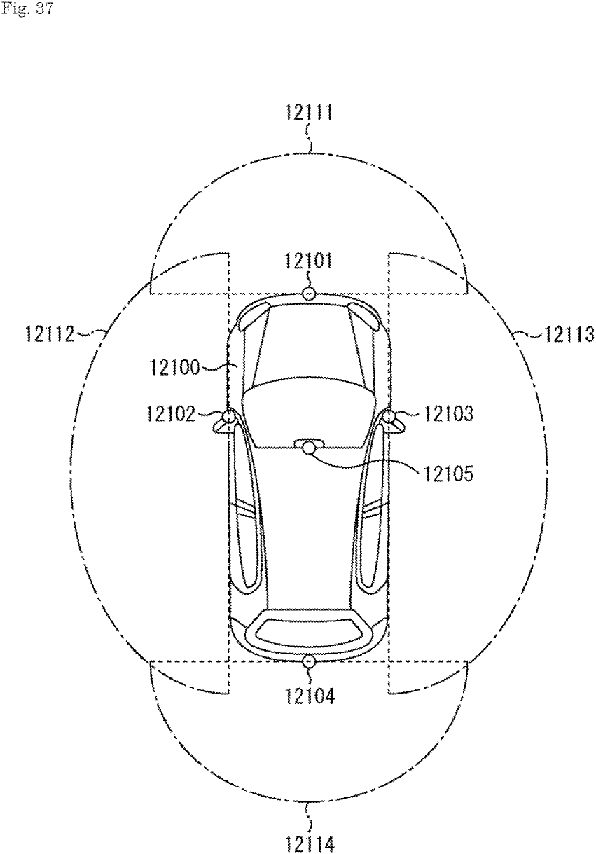

FIG. 1 is a block diagram illustrating a schematic configuration example of a light receiving element to which the present technology is applied.

A light receiving element 1 illustrated in FIG. 1 is a distance measurement sensor that outputs distance measurement information based on an indirect ToF scheme.

The light receiving element 1 receives light (reflected light) obtained by reflection of light emitted from a predetermined light source (irradiation light) and hitting against an object, and outputs a depth image in which information on a distance to the object is stored as depth values. Note that the irradiation light emitted from the light source is infrared light with a wavelength of equal to or greater than 780 nm, for example, and is pulse light that repeatedly turns on and off at a predetermined cycle.

The light receiving element 1 includes a pixel array portion 21 formed on a semiconductor substrate, which is not illustrated, and a peripheral circuit portion. The peripheral circuit portion includes, for example, a vertical drive portion 22, a column processing portion 23, a horizontal drive portion 24, a system control portion 25, and the like.

The light receiving element 1 is further provided with a signal processing portion 26 and a data storage portion 27. Note that the signal processing portion 26 and the data storage portion 27 may be mounted on the same substrate as that of the light receiving element 1, and may be disposed on a substrate in a module different from that the light receiving element 1.

The pixel array portion 21 generates charge corresponding to the amount of received light and is configured such that pixels 10 outputting signals corresponding to the charge are disposed in a matrix shape in a row direction and a column direction. In other words, the pixel array portion 21 includes a plurality of pixels 10 that perform photoelectric conversion on incident light and output signals in accordance with a charge obtained as a result. Details of the pixels 10 will be described later in FIG. 2 and the subsequent drawings.

Here, the row direction is a direction in which the pixels 10 are arranged in the horizontal direction, and the column direction is a direction in which the pixels 10 are arranged in the vertical direction. The row direction is a transverse direction in the drawing, and the column direction is a longitudinal direction in the drawing.

In the pixel array portion 21, a pixel drive line 28 is wired in the row direction for each pixel row and two vertical signal lines 29 are wired in the column direction for each pixel column in a pixel array having a matrix shape. For example, the pixel drive line 28 transfers a driving signal for driving at the time of reading signals from the pixels 10. Note that although the pixel drive line 28 is illustrated as one wire in FIG. 1, the number thereof is not limited to one. One end of the pixel drive line 28 is connected to an output end corresponding to each row of the vertical drive portion 22.

The vertical drive portion 22, which is constituted by a shift register, an address decoder, or the like, drives all of the pixels 10 of the pixel array portion 21 at the same time, in units of rows, or the like. In other words, the vertical drive portion 22 configures a control circuit that controls operations of each pixel 10 in the pixel array portion 21 along with the system control portion 25 that controls the vertical drive portion 22.

A pixel signal output from each pixel 10 in a pixel row in accordance with drive control performed by the vertical drive portion 22 is input to the column processing portion 23 through a vertical signal line 29. The column processing portion 23 performs predetermined signal processing on the pixel signal output from each pixel 10 through the vertical signal line 29 and temporarily holds the pixel signal after the signal processing. Specifically, the column processing portion 23 performs noise removing processing, analog-to-digital (AD) conversion processing, and the like as the signal processing.

The horizontal drive portion 24 is configured with a shift register, an address decoder, or the like and selects the unit circuits corresponding to the pixel column of the column processing portion 23 in sequence. Pixel signals on which the signal processing has been performed by the column processing portion 23 for each unit circuit are output in order through selective scanning performed by the horizontal drive portion 24.

The system control portion 25, which is constituted by a timing generator for generating various timing signals or the like, performs driving control of the vertical drive portion 22, the column processing portion 23, the horizontal drive portion 24, and the like on the basis of the various timing signals generated by the timing generator.

The signal processing portion 26 has at least an arithmetic operation processing function and performs various kinds of signal processing such as arithmetic operation processing on the basis of the pixel signals output from the column processing portion 23. The data storage portion 27 temporarily stores data required for signal processing performed by the signal processing portion 26 when the signal processing is performed.

The light receiving element 1 configured as described above has a circuit configuration called a column ADC type, in which AD conversion circuits that perform AD conversion processing are arranged for each pixel array in the column processing portion 23.

The light receiving element 1 outputs a depth image in which information on the distance to the object is stored as a depth value in a pixel value. The light receiving element 1 is mounted in a vehicle, for example, is mounted in an in-vehicle system for measuring the distance to an object outside the vehicle, or is mounted on a smartphone or the like and is used for gesture recognition processing or the like of measuring the distance to an object such as a user’s hand and recognizing a user’s gesture on the basis of a measurement result.

### 2. Sectional View According to First Configuration Example of Pixel

FIG. 2 is a sectional view illustrating a first configuration example of the pixels 10 disposed in the pixel array portion 21.

The light receiving element 1 includes a semiconductor substrate 41 and a multilayer wiring layer 42 formed on its front surface side (the lower side in the drawing).

The semiconductor substrate 41 is configured of silicon (hereinafter, referred to as Si), for example, and is formed to have a thickness of 1 to 10 µm, for example. In the semiconductor substrate 41, N-type (second conductive type) semiconductor regions 52 are formed in units of pixels in a P-type (first conductive type) semiconductor region 51, and thus photodiodes PD are formed in units of pixels, for example. Here, the P-type semiconductor regions 51 are configured of Si regions, which is a substrate material, while the N-type semiconductor regions 52 are configured of SiGe regions obtained by adding Si to germanium (hereinafter, referred to as Ge). The SiGe regions as the N-type semiconductor regions 52 can be formed by implanting Ge in the Si regions or through epitaxial growth as will be described later. Note that the N-type semiconductor regions 52 may be configured only of Ge rather than as the SiGe regions.

In FIG. 2, the upper surface of the semiconductor substrate 41 which is an upper side is the rear surface of the semiconductor substrate 41 and is a light incidence surface on which light is incident. An antireflection film 43 is formed on the upper surface of the semiconductor substrate 41 on the rear surface side.

The antireflection film 43 has a laminated structure in which, for example, a fixed charge film and an oxide film are laminated, and for example, an insulated thin film having a high dielectric constant (High-k) according to an atomic layer deposition (ALD) method can be used. Specifically, hafnium oxide (HfO₂), aluminum oxide (Al₂O₃), titanium oxide (TiO₂), strontium titan oxide (STO), and the like can be used. In the example of FIG. 2, the antireflection film 43 is configured by stacking a hafnium oxide film 53, an aluminum oxide film 54, and a silicon oxide film 55.

An inter-pixel light shielding film 45 that prevents incident light from being incident on adjacent pixels is formed at a boundary portion 44 of the adjacent pixels 10 (hereinafter, also referred to as a pixel boundary portion 44) on the semiconductor substrate 41 on the upper surface of the antireflection film 43. As a material of the inter-pixel light shielding film 45, any material that shields light may be used, and it is possible to use a metal material such as tungsten (W), aluminum (Al), or copper (Cu), for example.

A flattened film 46 is formed of an insulating film of silicon oxide (SiO₂), silicon nitride (SiN), silicon oxynitride (SiON), or the like or an organic material such as a resin, for example, on the upper surface of the antireflection film 43 and the upper surface of the inter-pixel light shielding film 45.

An on-chip lens 47 is formed for each pixel on the upper surface of the flattened film 46. The on-chip lens 47 is formed of, for example, a resin material such as a styrene resin, an acrylic resin, a styrene-acrylic copolymer resin, or a siloxane resin. Light collected by the on-chip lens 47 is efficiently incident on a photodiode PD.

A moth eye structure portion 71 in which fine irregularities are periodically formed is formed on the rear surface of the semiconductor substrate 41 above the region where the photodiode PD is formed. In addition, the antireflection film 43 formed on the upper surface is also formed to have a moth eye structure corresponding to the moth eye structure portion 71 of the semiconductor substrate 41.

The moth eye structure portion 71 of the semiconductor substrate 41 is configured such that regions of a plurality of quadrangular pyramids having substantially the same shape and substantially the same size are regularly (in a grid pattern) provided, for example.

The moth eye structure portion 71 is formed to have, for example, an inverted pyramid structure in which a plurality of regions having quadrangular pyramid shapes having vertices on the photodiode PD side are arranged to be lined up regularly.

Alternatively, the moth eye structure portion 71 may have a forward pyramid structure in which regions of a plurality of quadrangular pyramids having vertices on the on-chip lens 47 side are arranged to be lined up regularly. The sizes and arrangement of the plurality of quadrangular pyramids may be formed randomly instead of being regularly arranged. In addition, concave portions or convex portions of the quadrangular pyramids of the moth eye structure portion 71 have a certain degree of curvature and may have a rounded shape. The moth eye structure portion 71 is only required to have a structure in which a concave-convex structure is repeated periodically or randomly, and the shape of the concave portion or the convex portion is arbitrary.

In this manner, it is possible to moderate a sudden change in refractive index at the substrate interface and to reduce an influence of the reflected light by forming the moth eye structure portion 71 as a diffraction structure that diffracts incident light on the light incidence surface of the semiconductor substrate 41.

At the pixel boundary portion 44 on the rear surface side of the semiconductor substrate 41, an inter-pixel separation portion 61 that separates adjacent pixels is formed in the depth direction of the semiconductor substrate 41 up to a predetermined depth in the substrate depth direction from the rear surface side (the side of the on-chip lens 47) of the semiconductor substrate 41. Note that the depth of the formation of the inter-pixel separation portion 61 in the substrate thickness direction can be an arbitrary depth, and the inter-pixel separation portion 61 may penetrate through the semiconductor substrate 41 from the rear surface side to the front surface side to obtain complete separation in units of pixels. An outer circumferential portion including the bottom surface and the sidewall of the inter-pixel separation portion 61 is covered with the hafnium oxide film 53 which is a part of the antireflection film 43. The inter-pixel separation portion 61 prevents incident light from penetrating the next pixel 10 and being confined in its own pixel, and prevent leakage of incident light from the adjacent pixel 10.

In the example of FIG. 2, a silicon oxide film 55 which is a material of the uppermost layer of the antireflection film 43 is buried in a trench (a groove) carved on the rear surface side, and thus the silicon oxide film 55 and the inter-pixel separation portion 61 are simultaneously formed. Therefore, the inter-pixel separation portion 61 and the silicon oxide film 55 which is a part of stacked films serving as the antireflection film 43 are formed of the same material, but may not be formed of the same material. A material with which a trench (groove) dug from the rear surface side as the inter-pixel separation portion 61 is buried may be, for example, a metal material such as tungsten (W), aluminum (Al), titanium (Ti), or titanium nitride (TiN).

On the other hand, two transfer transistors TRG1 and TRG2 are formed for one photodiode PD formed for each pixel 10 on the front surface side of the semiconductor substrate 41 where the multilayer wiring layer 42 is formed. Also, floating diffusion regions FD1 and FD2 that serve as charge holding portions for temporarily holding charge transferred from the photodiode PD are formed by high-concentration N-type semiconductor regions (N-type diffusion regions) on the front surface side of the semiconductor substrate 41.

The multilayer wiring layer 42 is configured by a plurality of metal films M and insulating interlayer films 62 therebetween. Although the example in which three layers, namely the first metal film M1 to the third metal film M3, are included in the configuration is illustrated in FIG. 2, the number of layers of the metal films M is not limited to three.

A metal wiring of copper, aluminum, or the like is formed as the light shielding member 63 in a region located below a region where the photodiode PD is formed in the first metal film M1 that is the closest to the semiconductor substrate 41 among the plurality of metal films M in the multilayer wiring layer 42, in other words, a region that partially overlaps the region where the photodiode PD is formed in a plan view.

The light shielding member 63 shields, with the first metal film M1 that is the closest to the semiconductor substrate 41, infrared light that is incident on the inside of the semiconductor substrate 41 from the light incidence surface via the on-chip lens 47 and penetrates through the semiconductor substrate 41 without being photoelectrically converted inside the semiconductor substrate 41 and prevents the infrared light from being transmitted to the second metal film M2 and the third metal film M3 on the yet lower side. With this light shielding function, it is possible to curb the infrared light that has penetrated through the semiconductor substrate 41 without being photoelectrically converted inside the semiconductor substrate 41 from being scattering by the metal films M below the first metal film M1 and being incident on the surrounding pixels. It is thus possible to prevent light from being detected erroneously in the surrounding pixels.

Also, the light shielding member 63 also has a function of causing the infrared light that is incident on the inside of the semiconductor substrate 41 from the light incidence surface via the on-chip lens 47 and penetrates through the semiconductor substrate 41 without being photoelectrically converted inside the semiconductor substrate 41 to be reflected by the light shielding member 63 and be incident on the inside of the semiconductor substrate 41 again. Therefore, it is also possible to call the light shielding member 63 a reflecting member. Such a reflecting function can lead to a further increase in the amount of infrared light to be photoelectrically converted inside the semiconductor substrate 41 and to an improvement in quantum efficiency (QE), that is, sensitivity of the pixels 10 with respect to the infrared light.

Note that the light shielding member 63 may form a structure in which reflection or light shielding is achieved by polysilicon, an oxide film, or the like as well as the metal material.

Also, the light shielding member 63 may be configured of a plurality of metal films M, for example, the light shielding member 63 may be formed into a grid shape by the first metal film M1 and the second metal film M2, instead of the configuration of the single metal film M.

A wiring capacitor 64 is formed in a predetermined metal film M, for example, the second metal film M2 from among the plurality of metal films M in the multilayer wiring layer 42, through pattern formation into a comb-teeth shape in a plan view, for example. Although the light shielding member 63 and the wiring capacitor 64 may be formed in the same layer (metal film M), the wiring capacitor 64 is formed in a layer that is further from the semiconductor substrate 41 than the light shielding member 63 in a case where they are formed in different layers. In other words, the light shielding member 63 is formed closer to the semiconductor substrate 41 than the wiring capacitor 64.

As described above, the light receiving element 1 has a rear surface irradiation type structure in which the semiconductor substrate 41 which is a semiconductor layer is disposed between the on-chip lens 47 and the multilayer wiring layer 42 and incident light is incident on the photodiode PD from the rear surface side where the on-chip lens 47 is formed.

Also, the pixel 10 includes two transfer transistors TRG1 and TRG2 for the photodiode PD provided for each pixel and is configured to be able to sort charges (electrons) generated through photoelectric conversion by the photodiode PD into the floating diffusion region FD1 or FD2.

Furthermore, the pixel 10 prevents the incident light from braking through to the next pixels 10, to trap the incident light in the pixel itself, and to prevent the incident light from leaking from the adjacent pixels 10, by forming the inter-pixel separation portion 61 at the pixel boundary portion 44. Also, the infrared light that has penetrated through the semiconductor substrate 41 without being photoelectrically converted inside the semiconductor substrate 41 is reflected by the light shielding member 63 and is then caused to be incident again on the inside of the semiconductor substrate 41, by providing the light shielding member 63 in the metal film M below the region where the photodiode PD is formed.

Also, the N-type semiconductor region 52 which is a photoelectric conversion region is formed of an SiGe region or a Ge region in the pixel 10. Since SiGe and Ge have narrower band gaps than Si, it is possible to enhance quantum efficiency of the near-infrared light.

With the aforementioned configuration, it is possible to further increase the amount of infrared light to be photoelectrically converted inside the semiconductor substrate 41 and to improve quantum efficiency (QE), that is, sensitivity to infrared light according to the light receiving element 1 including the pixels 10 according to the first configuration example.

### 3. Circuit Configuration Example of Pixel

FIG. 3 illustrates a circuit configuration of each pixel 10 which is two-dimensionally disposed in the pixel array portion 21.

The pixel 10 includes the photodiode PD as a photoelectric conversion element. In addition, the pixel 10 includes two transfer transistors TRG, two floating diffusion regions FD, two additional capacitors FDL, two switching transistors FDG, two amplification transistors AMP, two reset transistors RST, and two selection transistors SEL. Further, the pixel 10 includes a charge discharging transistor OFG.

Here, in a case where the two transfer transistors TRG, the two floating diffusion regions FD, the two additional capacitors FDL, the two switching transistors FDG, the two amplification transistors AMP, the two reset transistors RST, and the two selection transistors SEL which are provided in the pixel 10 are distinguished from each other, they will be referred to as transfer transistors TRG1 and TRG2, floating diffusion regions FD1 and FD2, additional capacitors FDL1 and FDL2, switching transistors FDG1 and FDG2, amplification transistors AMP1 and AMP2, reset transistors RST1 and RST2, and selection transistors SEL1 and SEL2, respectively, as illustrated in FIG. 3.

The transfer transistors TRG, the switching transistors FDG, the amplification transistors AMP, the selection transistors SEL, the reset transistors RST, and the charge discharging transistors OFG are configured by, for example, N-type MOS transistors.

The transfer transistor TRG1 transfers charges accumulated in the photodiode PD to the floating diffusion region FD1 by being brought into a conductive state in response to a transfer driving signal TRG1g supplied to a gate electrode being brought into an active state. The transfer transistor TRG2 transfers charges accumulated in the photodiode PD to the floating diffusion region FD2 by being brought into a conductive state in response to a transfer driving signal TRG2g supplied to the gate electrode being brought into an active state.

The floating diffusion regions FD1 and FD2 are charge holding portions that temporarily hold the charges transferred from the photodiode PD.

The switching transistor FDG1 causes the additional capacitor FDL1 to be connected to the floating diffusion region FD1 by being brought into a conductive state in response to an FD driving signal FDG1g supplied to the gate electrode being brought into an active state. The switching transistor FDG2 causes the additional capacitor FDL2 to be connected to the floating diffusion region FD2 by being brought into a conductive state in response to an FD driving signal FDG2g supplied to the gate electrode being brought into an active state. The additional capacitors FDL1 and FDL2 are formed by the wiring capacitor 64 in FIG. 2.

The reset transistor RST1 resets the potential of the floating diffusion region FD1 by being brought into a conductive state in response to a reset driving signal RSTg supplied to the gate electrode being brought into an active state. The reset transistor RST2 resets the potential of the floating diffusion region FD2 by being brought into a conductive state in response to a reset driving signal RSTg supplied to the gate electrode being brought into an active state. Note that when the reset transistors RST1 and RST2 are brought into the active state, the switching transistors FDG1 and FDG2 are also brought into an active state, and the additional capacitors FDL1 and FDL2 are also reset.

The vertical drive portion 22 brings the switching transistors FDG1 and FDG2 into an active state, connects the floating diffusion region FD1 to the additional capacitor FDL1, and connects the floating diffusion region FD2 to the additional capacitor FDL2 at the time of high illuminance when the amount of incident light is large. Accordingly, a larger amount of charges can be accumulated at the time of high illuminance.

On the other hand, the vertical drive portion 22 brings the switching transistors FDG1 and FDG2 into a non-active state and disconnects the additional capacitors FDL1 and FDL2 from the floating diffusion regions FD1 and FD2, respectively, at the time of low illuminance when the amount of incident light is small. Accordingly, conversion efficiency can be improved.

The charge discharging transistor OFG discharges charges accumulated in the photodiode PD by being brought into a conductive state in response to a discharge drive signal OFG1g supplied to the gate electrode being brought into an active state.

The amplification transistor AMP1 is connected to a constant current source, which is not illustrated, and configures a source follower circuit by a source electrode being connected to the vertical signal line 29A via the selection transistor SEL1. The amplification transistor AMP2 is connected to a constant current source, which is not illustrated, and configures a source follower circuit by a source electrode being connected to the vertical signal line 29B via the selection transistor SEL2.

The selection transistor SEL1 is connected between the source electrode of the amplification transistor AMP1 and the vertical signal line 29A. The selection transistor SEL1 is brought into a conductive state in response to a selection signal SEL1g supplied to the gate electrode being brought into an active state and outputs a pixel signal VSL1 output from the amplification transistor AMP1 to the vertical signal line 29A.

The selection transistor SEL2 is connected between the source electrode of the amplification transistor AMP2 and the vertical signal line 29B. The selection transistor SEL2 is brought into a conductive state in response to a selection signal SEL2g supplied to the gate electrode being brought into an active state and outputs a pixel signal VSL2 output from the amplification transistor AMP2 to the vertical signal line 29B.

The transfer transistors TRG1 and TRG2, the switching transistors FDG1 and FDG2, the amplification transistors AMP1 and AMP2, the selection transistors SEL1 and SEL2, and the charge discharging transistor OFG of the pixel 10 are controlled by the vertical drive portion 22.

Although the additional capacitors FDL1 and FDL2 and the switching transistors FDG1 and FDG2 which control connection thereof may be omitted in the pixel circuit in FIG. 3, it is possible to secure a high dynamic range by providing the additional capacitors FDL and separately using the additional capacitors FDL in accordance with the amount of incident light.

Operations of the pixel 10 in FIG. 3 will be briefly described.

First, a reset operation for resetting charges in the pixels 10 is performed in all the pixels before receiving of light is started. In other words, the charge discharging transistor OFG, the reset transistors RST1 and RST2, the switching transistors FDG1 and FDG2 are turned on, and charges accumulated in the photodiode PD, the floating diffusion regions FD1 and FD2, and the additional capacitors FDL1 and FDL2 are discharged.

After the accumulated charges are discharged, receiving of light is started in all the pixels. In the light receiving period, the transfer transistors TRG1 and TRG2 are alternately driven. In other words, control of turning on the transfer transistor TRG1 and turning off the transfer transistor TRG2 is performed in a first period. In the first period, charges generated in the photodiode PD is transferred to the floating diffusion region FD1. In a second period after the first period, control of turning on the transfer transistor TRG1 and turning off the transfer transistor TRG2 is performed. In the second period, charges generated in the photodiode PD is transferred to the floating diffusion region FD2. In this manner, the charges generated in the photodiode PD are alternately sorted to and accumulated in the floating diffusion regions FD1 and FD2.

In addition, when the light receiving period ends, each pixel 10 in the pixel array portion 21 is selected in a line-sequential manner. In the selected pixel 10, the selection transistors SEL1 and SEL2 are turned on. In this manner, the charges accumulated in the floating diffusion region FD1 are output as a pixel signal VSL1 to the column processing portion 23 via the vertical signal line 29A. The charges accumulated in the floating diffusion region FD2 are output as a pixel signal VSL2 to the column processing portion 23 via the vertical signal line 29B.

As described above, one light receiving operation is terminated, and the next light receiving operation starting from the reset operation is executed.

Reflected light received by the pixel 10 is delayed in accordance with a distance to the object from a timing when the light source emits light. Since the distribution ratio of the charges accumulated in the two floating diffusion regions FD1 and FD2 changes depending on the delay time in accordance with the distance to the object, it is possible to obtain the distance to the object from the distribution ratio of the charges accumulated in the two floating diffusion regions FD1 and FD2.

### 4. Plan View of Pixel

FIG. 4 is a plan view illustrating an example of arrangement of the pixel circuit illustrated in FIG. 3.

The transverse direction in FIG. 4 corresponds to a row direction (horizontal direction) in FIG. 1, and the longitudinal direction corresponds to a column direction (vertical direction) in FIG. 1.

As illustrated in FIG. 4, the photodiode PD is formed of the N-type semiconductor region 52 in the region at the center portion of the rectangular pixel 10, and the region is an SiGe region.

The transfer transistor TRG1, the switching transistor FDG1, the reset transistor RST1, the amplification transistor AMP1, and the selection transistor SEL1 are disposed in a linearly aligned manner outside the photodiode PD and along a predetermined one side out of the four sides of the rectangular pixel 10, and the transfer transistor TRG2, the switching transistor FDG2, the reset transistor RST2, the amplification transistor AMP2, and the selection transistor SEL2 are disposed in a linearly aligned manner along another side out of the four sides of the rectangular pixel 10.

Further, the charge discharging transistor OFG is disposed at a side different from the two sides of the pixel 10 where the transfer transistors TRG, the switching transistors FDG, the reset transistors RST, the amplification transistors AMP, and the selection transistors SEL are formed.

Note that the arrangement of the pixel circuit illustrated in FIG. 3 is not limited to this example and may be other arrangement.

### 5. Other Circuit Configuration Examples of Pixel

FIG. 5 illustrates other circuit configuration examples of the pixel 10.

In FIG. 5, portions corresponding to those in FIG. 3 are denoted by the same reference numerals and signs, and description of the portions will be appropriately omitted.

The pixel 10 includes the photodiode PD as a photoelectric conversion element. In addition, the pixel 10 includes two first transfer transistors TRGa, two second transfer transistors TRGb, two memories MEM, two floating diffusion regions FD, two reset transistors RST, two amplification transistors AMP, and two selection transistors SEL.

Here, in a case where the two first transfer transistors TRGa, the two second transfer transistors TRGb, the two memories MEM, the two floating diffusion regions FD, the two reset transistors RST, the two amplification transistors AMP, and the two selection transistors SEL which are provided in the pixel 10 are distinguished from each other, they will be referred to as first transfer transistors TRGa1 and TRGa2, second transfer transistors TRGb1 and TRGb2, transfer transistors TRG1 and TRG2, memories MEM1 and MEM2, floating diffusion regions FD1 and FD2, amplification transistors AMP1 and AMP2, and selection transistors SEL1 and SEL2, respectively, as illustrated in FIG. 5.

Thus, comparing the pixel circuit in FIG. 3 with the pixel circuit in FIG. 5, the transfer transistors TRG are changed to two types of transfer transistors, namely, first transfer transistors TRGa and second transfer transistors TRGb, and the memories MEM are added. In addition, the additional capacitor FDL and the switching transistor FDG are omitted.

The first transfer transistors TRGa, the second transfer transistors TRGb, the reset transistors RST, the amplification transistors AMP, and selection transistors SEL are configured by, for example, N-type MOS transistors.

Although charges generated by the photodiode PD are transferred to and held in the floating diffusion regions FD1 and FD2 in the pixel circuit illustrated in FIG. 3, the charges are transferred to and held in the memories MEM1 and MEM2 newly provided as charge holding portions in the pixel circuit in FIG. 5.

In other words, the first transfer transistor TRGa1 is brought into a conductive state in response to a first transfer driving signal TRGa1g supplied to a gate electrode being brought into an active state, and thus transfers the charges accumulated in the photodiode PD to the memory MEM1. The first transfer transistor TRGa2 is brought into a conductive state in response to a first transfer driving signal TRGa2g supplied to the gate electrode being brought into an active state, and thus transfers the charges accumulated in the photodiode PD to the memory MEM2.

Also, the second transfer transistor TRGb1 is brought into a conductive state in response to a second transfer driving signal TRGb1g supplied to the gate electrode being brought into an active state, and thus transfers the charges held in the memory MEM1 to the floating diffusion region FD1. The second transfer transistor TRGb2 is brought into a conductive state in response to a second transfer driving signal TRGb2g supplied to the gate electrode being brought into an active state, and thus transfers the charges held in the memory MEM2 to the floating diffusion region FD2.

The reset transistor RST1 is brought into a conductive state in response to a reset driving signal RST1g supplied to the gate electrode being brought into an active state, and thus resets the potential of the floating diffusion region FD1. The reset transistor RST2 is brought into a conductive state in response to a reset driving signal RST2g supplied to the gate electrode being brought into an active state, and thus resets the potential of the floating diffusion region FD2. Note that when the reset transistors RST1 and RST2 are brought into an active state, the second transfer transistors TRGb1 and TRGb2 are also brought into an active state, and the memories MEM1 and MEM2 are also reset.

In the pixel circuit in FIG. 5, the charges generated by the photodiode PD are sorted to and accumulated in the memories MEM1 and MEM2. Then, the charges held in the memories MEM1 and MEM2 are transferred to the floating diffusion regions FD1 and FD2, respectively, and are then output from the pixel 10 at the timing of reading.

### 6. Plan View of Pixel

FIG. 6 is a plan view illustrating an example of arrangement of a pixel circuit illustrated in FIG. 5.

A transverse direction in FIG. 6 corresponds to a row direction (horizontal direction) in FIG. 1, and a longitudinal direction corresponds to a column direction (vertical direction) in FIG. 1.

As illustrated in FIG. 6, an N-type semiconductor region 52 that serves as the photodiode PD in the rectangular pixel 10 is formed of an SiGe region.

The first transfer transistor TRGa1, the second transfer transistor TRGb1, the reset transistor RST1, the amplification transistor AMP1, and the selection transistor SEL1 are disposed in a linearly aligned manner outside the photodiode PD along a predetermined side out of the four sides of the rectangular pixel 10, and the first transfer transistor TRGa2, the second transfer transistor TRGb2, the reset transistor RST2, the reset transistor RST2, the amplification transistor AMP2, and the selection transistor SEL2 are disposed in a linearly aligned manner along another side out of the four sides of the rectangular pixels 10. The memories MEM1 and MEM2 are configured by, for example, embedded N-type diffusion regions.

Note that the arrangement of the pixel circuit illustrated in FIG. 5 is not limited to this example and may be other arrangement.

### 7. Formation Method for GeSi Region

FIG. 7 is a plan view illustrating an arrangement example of 3 × 3 pixels 10 from among the plurality of pixels 10 in the pixel array portion 21.

In a case where only the N-type semiconductor region 52 of each pixel 10 is formed of the SiGe region, arrangement in which the SiGe regions are separated in units of pixels as illustrated in FIG. 7 is obtained when the entire region of the pixel array portion 21 is seen.

FIG. 8 is a sectional view of the semiconductor substrate 41 for explaining a first formation method in which the N-type semiconductor regions 52 are formed of SiGe regions.

According to the first formation method, it is possible to form the N-type semiconductor regions 52 as SiGe regions by selectively implanting Ge ions in parts serving as the N-type semiconductor regions 52 in the semiconductor substrate 41 which is an Si region using a mask as illustrated in FIG. 8. The region other than the N-type semiconductor regions 52 in the semiconductor substrate 41 serves as a P-type semiconductor region 51, which is an Si region.

FIG. 9 is a sectional view of the semiconductor substrate 41 for explaining a second formation method in which the N-type semiconductor regions 52 are formed of SiGe regions.

According to the second formation method, the parts corresponding to Si regions that serve as the N-type semiconductor regions 52 in the semiconductor substrate 41 are removed as illustrated in FIG. 9A first. Also, the N-type semiconductor regions 52 are formed of SiGe regions by forming films of SiGe layers in the removed regions through epitaxial growth as illustrated in FIG. 9B.

Note that FIG. 9 illustrates an example in which arrangement of pixel transistors is arrangement that is different from the arrangement illustrated in FIG. 4 and the amplification transistors AMP1 are disposed in the vicinity of the N-type semiconductor regions 52 formed of SiGe regions.

As described above, the N-type semiconductor regions 52 that serve as the SiGe regions can be formed by the first formation method in which Ge ions are implanted in the Si regions or the second formation method in which the SiGe layers are formed through epitaxial growth. It is also possible to form the N-type semiconductor regions 52 by similar methods even in a case where the N-type semiconductor regions 52 are formed of Ge regions.

### 8. Modification Example of First Configuration Example

Although the configuration in which only the N-type semiconductor regions 52 which are photoelectric conversion regions in the semiconductor substrate 41 are formed of the SiGe regions or the Ge regions has been employed for the pixels 10 according to the aforementioned first configuration example, the P-type semiconductor regions 51 below the gates of the transfer transistors TRG may also be formed of P-type SiGe regions or Ge regions.

FIG. 10 is a diagram illustrating planar arrangement of the pixel circuit in FIG. 3 illustrated in FIG. 4 again, and the P-type regions 81 below the gates of the transfer transistors TRG1 and TRG2 illustrated by the dashed lines in FIG. 10 are formed of SiGe regions or Ge regions. It is possible to enhance channel mobility of the transfer transistors TRG1 and TRG2 which are driven at a high speed by forming the channel regions of the transfer transistors TRG1 and TRG2 by the SiGe regions or the Ge regions.

In a case where the channel regions of the transfer transistors TRG1 and TRG2 are formed of the SiGe regions using epitaxial growth, the parts where the N-type semiconductor regions 52 are formed in the semiconductor substrate 41 and the parts below the gates of the transfer transistors TRG1 and TRG2 are removed first as illustrated in FIG. 11A. Then, films of SiGe layers are formed in the removed regions through epitaxial growth, and the N-type semiconductor regions 52 and the regions below the gates of the transfer transistors TRG1 and TRG2 are thus formed of SiGe regions as illustrated in FIG. 11B.

Here, there is a problem that a dark current generated from the floating diffusion regions FD increases if the floating diffusion regions FD1 and FD2 are formed in the formed SiGe regions. Therefore, a structure in which an Si layer is further formed on the formed SiGe layer through epitaxial growth and a high-concentration N-type semiconductor region (N-type diffusion region) is formed and caused to serve as the floating diffusion region FD as illustrated in FIG. 11B is employed in the case where the transfer transistor TRG formation region is formed of the SiGe region. It is thus possible to suppress the dark current from the floating diffusion region FD.

The P-type semiconductor regions 51 below the gates of the transfer transistors TRG may be formed of SiGe regions through selective ion implantation using a mask instead of the epitaxial growth, and it is also possible to further form Si layers on the formed SiGe layer through epitaxial growth and cause them to serve as the floating diffusion regions FD1 and FD2 in a similar manner in this case as well.

### 9. Substrate Configuration Example of Light Receiving Element

FIG. 12 is a schematic perspective view illustrating a substrate configuration example of the light receiving element 1.

There may be a case where the light receiving element 1 is formed in one semiconductor substrate and a case where the light receiving element 1 is formed in a plurality of semiconductor substrates.

FIG. 12A illustrates a schematic configuration example in the case where the light receiving element 1 is formed in one semiconductor substrate.

In the case where the light receiving element 1 is formed in one semiconductor substrate, a pixel array region 111 corresponding to the pixel array portion 21 and a logic circuit region 112 corresponding to a circuit other than the pixel array portion 21, for example, a control circuit for the vertical drive portion 22, the horizontal drive portion 24, and the like, an arithmetic operation circuit for the column processing portion 23 and the signal processing portion 26, and the like are formed on the one semiconductor substrate 41 in an aligned manner in a planar direction as illustrated in FIG. 12A. The sectional configuration illustrated in FIG. 2 is the configuration of one substrate.

On the other hand, FIG. 12B illustrates a schematic configuration example in the case where the light receiving element 1 are formed in a plurality of semiconductor substrates.

In the case where the light receiving element 1 is formed in a plurality of semiconductor substrates, the pixel array region 111 is formed in the semiconductor substrate 41 while the logic circuit region 112 is formed in another semiconductor substrate 141, and the semiconductor substrate 41 and the semiconductor substrate 141 are configured to be laminated, as illustrated in FIG. 12B.

The following description will be given by referring the semiconductor substrate 41 as a first substrate 41 and referring the semiconductor substrate 141 as a second substrate 141 in the case of the laminated structure for easiness of explanation.

### 10. Pixel Sectional View in a Case of Laminated Structure

FIG. 13 illustrates a sectional view of pixels 10 in a case where the light receiving element 1 is configured to have a laminated structure of two substrates.

In FIG. 13, parts corresponding to those in the first configuration example illustrated in FIG. 2 are denoted by the same reference signs, and description of the parts will be appropriately omitted.

The laminated structure in FIG. 13 is configured using two semiconductor substrates, namely the first substrate 41 and the second substrate 141 as described above in FIG. 12.

The laminated structure in FIG. 13 is similar to that in the first configuration example in FIG. 2 in that the inter-pixel light shielding film 45, the flattened film 46, the on-chip lens 47, and the moth eye structure portion 71 are formed on the light incidence surface side of the first substrate 41. The laminated structure in FIG. 13 is also similar to that in the first configuration example of FIG. 2 in that the inter-pixel separation portion 61 is formed at the pixel boundary portion 44 on the rear surface side of the first substrate 41.

Additionally, the configuration examples are similar to each other in that the photodiodes PD are formed in the first substrate 41 in units of pixels and the two transfer transistors TRG1 and TRG2 and the floating diffusion regions FD1 and FD2 that serve as charge holding portions are formed on the front surface side of the first substrate 41.

On the other hand, the laminated structure in FIG. 13 is different from that in the first configuration example of FIG. 2 in that an insulating layer 153 which is a part of a wiring layer 151 corresponding to the front surface side of the first substrate 41 is attached to an insulating layer 152 in the second substrate 141.

The wiring layer 151 of the first substrate 41 includes at least one metal film M of a single layer, and the light shielding member 63 is formed in a region located below the region where the photodiode PD is formed using the metal film M.

Pixel transistors Tr1 and Tr2 are formed at an interface on the side opposite to the side of the insulating layer 152 which is a side of the attached surface of the second substrate 141. The pixel transistors Tr1 and Tr2 are, for example, an amplification transistor AMP, a selection transistor SEL, and the like.

In other words, although all the pixel transistors of the transfer transistor TRG, the switching transistor FDG, the amplification transistor AMP, and the selection transistor SEL are formed in the semiconductor substrate 41 in the first configuration example configured using only one semiconductor substrate 41 (first substrate 41), the pixel transistors other than the transfer transistor TRG, that is, the switching transistor FDG, the amplification transistor AMP, and the selection transistor SEL are formed in the second substrate 141 in the light receiving element 1 with the laminated structure of two semiconductor substrates.

A wiring layer 161 including at least metal films M of two layers is formed on the surface of the second substrate 141 on the side opposite to the side of the first substrate 41. The wiring layer 161 includes a first metal film M11, a second metal film M12, and an insulating layer 173.

A transfer driving signal TRG1g for controlling the transfer transistor TRG1 is supplied from the first metal film M11 of the second substrate 141 to the gate electrode of the transfer transistor TRG1 of the first substrate 41 by a through silicon via (TSV) 171-1 penetrating through the second substrate 141. A transfer driving signal TRG2g for controlling the transfer transistor TRG2 is supplied from the first metal film M11 of the second substrate 141 to the gate electrode of the transfer transistor TRG2 of the first substrate 41 by a TSV 171-2 penetrating through the second substrate 141.

Similarly, charges accumulated in the floating diffusion region FD1 are transmitted from the side of the first substrate 41 to the first metal film M11 of the second substrate 141 by a TSV 172-1 penetrating through the second substrate 141. Charges accumulated in the floating diffusion region FD2 are also transmitted from the side of the first substrate 41 to the first metal film M11 of the second substrate 141 by a TSV 172-2 penetrating through the second substrate 141.

The wiring capacitor 64 is formed in a region, which is not illustrated in the drawing, of the first metal film M11 or the second metal film M12. The metal film M having the wiring capacitor 64 formed therein is formed to have a high wiring density in order to form a capacity, and the metal film M connected to gate electrodes of the transfer transistors TRG, the switching transistors FDG, and the like is formed to have a low wiring density in order to reduce an induced current. A configuration in which a wiring layer (metal film M) connected to the gate electrode is different for each pixel transistor may be adopted.

As described above, the pixel 10 can be configured by laminating two semiconductor substrates, namely the first substrate 41 and the second substrate 141, and the pixel transistors other than the transfer transistors TRG are formed in the second substrate 141 which is different from the first substrate 41 including the photoelectric conversion portion. Also, the vertical drive portion 22 and the pixel drive line 28 for controlling driving of the pixel 10, the vertical signal line 29 for transmitting the pixel signal, and the like are also formed in the second substrate 141. In this manner, the pixel can be made fine, and the degree of freedom in back end of line (BEOL) design is also increased.

It is possible to secure a sufficient aperture as compared with the case of the front surface irradiation type and to maximize the quantum efficiency (QE) × aperture (FF) by employing the pixel structure of the rear surface irradiation type in the pixel 10 in FIG. 13 as well.

Also, it is possible to cause infrared light that has penetrated through the semiconductor substrate 41 without being photoelectrically converted inside the semiconductor substrate 41 to be reflected by the light shielding member 63 (reflecting member) and be incident on the inside of the semiconductor substrate 41 again by including the light shielding member 63 in a region overlapping the region where the photodiode PD is formed in the wiring layer 151 that is the closest to the first substrate 41. Also, it is possible to curb the infrared light that has penetrated through the semiconductor substrate 41 without being photoelectrically converted inside the semiconductor substrate 41 from being incident on the side of the second substrate 141.

Since the N-type semiconductor region 52 configuring the photodiode PD is formed of an SiGe region or a Ge region in the pixel 10 in FIG. 13 as well, it is possible to enhance quantum efficiency of near-infrared light.

With the aforementioned pixel structure, it is possible to further increase the amount of infrared light to be photoelectrically converted inside the semiconductor substrate 41, to enhance quantum efficiency (QE), and to improve sensitivity of the sensor.

### 11. Three-layer Laminated Structure

Although FIG. 13 illustrates an example in which the light receiving element 1 is configured of the two semiconductor substrates, the light receiving element 1 may be configured of three semiconductor substrates.

FIG. 14 illustrates a schematic sectional view of the light receiving element 1 formed by laminating three semiconductor substrates.

In FIG. 14, parts corresponding to those in FIG. 12 are denoted by the same reference signs, and description of the portions will be appropriately omitted.

The pixel 10 in FIG. 14 is configured by laminating one more semiconductor substrate 181 (hereinafter, referred to as a third substrate 181) in addition to the first substrate 41 and the second substrate 141.

At least the photodiode PD and the transfer transistors TRG are formed in the first substrate 41. An N-type semiconductor region 52 configuring the photodiode PD is formed of an SiGe region or a Ge region.

Pixel transistors other than the transfer transistors TRG, such as the amplification transistors AMP, the reset transistors RST, and the selection transistors SEL are formed in the second substrate 141.

Signal circuits for processing a pixel signal output from the pixel 10, such as the column processing portion 23 and the signal processing portion 26, are formed in the third substrate 181.

The first substrate 41 is of a rear surface irradiation type in which the on-chip lens 47 is formed on the rear surface side opposite to the front surface side on which the wiring layer 151 is formed and light is incident from the rear surface side of the first substrate 41.

The wiring layer 151 of the first substrate 41 is attached to the wiring layer 161 corresponding to the front surface side of the second substrate 141 through Cu-Cu bonding.

The second substrate 141 and the third substrate 181 are attached to each other through Cu-Cu bonding between a Cu film formed on a wiring layer 182 on the front surface side of the third substrate 181 and a Cu Film formed on the insulating layer 152 on the second substrate 141. The wiring layer 161 of the second substrate 141 and the wiring layer 182 of the third substrate 181 are electrically connected to each other via a through electrode 163.

Although the wiring layer 161 corresponding to the front surface side of the second substrate 141 is bonded to the wiring layer 151 of the first substrate 41 in a facing manner in the example in FIG. 14, the second substrate 141 may be vertically inverted, and the wiring layer 161 of the second substrate 141B may be bonded to face the wiring layer 182 of the third substrate 181.

### 12. Four-tap Pixel Configuration Example

The aforementioned pixel 10 has a pixel structure called two taps, in which the two transfer transistors TRG1 and TRG2 are included as transfer gates for the one photodiode PD, the two floating diffusion regions FD1 and FD2 are included as charge holding portions, and the charges generated by the photodiode PD are sorted to the two floating diffusion regions FD1 and FD2.

On the contrary, the pixel 10 can have a four-tap pixel structure in which four transfer transistors TRG1 to TRG4 and floating diffusion regions FD1 to FD4 are included for one photodiode PD and the charges generated in the photodiode PD are sorted to the four floating diffusion regions FD1 to FD4.

FIG. 15 is a plan view in a case where a memory MEM holding-type pixel 10 illustrated in FIGS. 5 and 6 has the four-tap pixel structure.

The pixel 10 includes four first transfer transistors TRGa, four second transfer transistors TRGb, four reset transistors RST, four amplification transistors AMP, and four selection transistors SEL.

A set of the first transfer transistor TRGa, the second transfer transistor TRGb, the reset transistor RST, the amplification transistor AMP, and the selection transistor SEL are disposed in a linearly aligned manner outside the photodiode PD and along each side of the four sides of the rectangular pixel 10.

In FIG. 15, each set of the first transfer transistor TRGa, the second transfer transistor TRGb, the reset transistor RST, the amplification transistor AMP, and the selection transistor SEL disposed along each side of the four sides of the rectangular pixel 10 is distinguished by applying any one of the numbers 1 to 4.

In a case where the pixel 10 has a two-tap structure, driving for sorting generated charged into the two floating diffusion regions FD is performed by causing phases (light receiving timings) of the first tap and the second tap to deviate by 180 degrees. On the other hand, in a case where the pixel 10 has a four-tap structure, it is possible to perform driving for sorting the generated charges into the four floating diffusion regions FD by causing phases (light receiving timings) of the first to fourth taps to deviate by 90 degrees. Also, it is possible to obtain the distance to the object on the basis of the distribution ratio of the charges accumulated in the four floating diffusion regions FD.

As described above, the pixel 10 can have the structure in which the charges generated by the photodiode PD are sorted by four taps as well as the structure in which the charges are sorted by two taps, and the number of taps is not limited to two and can be three or more. Note that even in a case where the pixel 10 has a one-tap structure, it is possible to obtain the distance to the object by causing phases to deviate in units of frames.

### 13. Other Formation Examples of SiGe Region

In the aforementioned configuration example of the light receiving element 1, the configuration in which only a partial region of each pixel 10, specifically, only the N-type semiconductor region 52 of the photodiode PD which is the photoelectric conversion region or the N-type semiconductor region 52 and the channel region below the gates of the transfer transistors TRG are formed of SiGe regions has been described. In this case, the SiGe regions are provided separately in units of pixels as illustrated in FIG. 7.

In next FIGS. 16 and 17, a configuration in which the entire pixel array region 111 (pixel array portion 21) is formed of an SiGe region will be described.

FIG. 16 illustrates a configuration example in which the entire pixel array region 111 is formed of an SiGe region in a case where the light receiving element 1 is formed on the one semiconductor substrate illustrated in FIG. 12A.

FIG. 16A is a plan view of the semiconductor substrate 41 in which the pixel array region 111 and the logic circuit region 112 are formed on the same substrate. FIG. 16B is a sectional view of the semiconductor substrate 41.

As illustrated in FIG. 16A, the entire pixel array region 111 can be formed of an SiGe region, and the other regions such as the logic circuit region 112 are formed of Si regions.

In regard to the pixel array region 111 formed of the SiGe region, it is possible to form the entire pixel array region 111 by the SiGe region by implanting Ge ions in the part that serves as the pixel array region 111 in the semiconductor substrate 41 which is the Si region as illustrated in FIG. 16B.

FIG. 17 illustrates a configuration example in which the entire pixel array region 111 is formed of the SiGe region in a case where the light receiving element 1 is formed to have a laminated structure of two semiconductor substrates illustrated in FIG. 12B.

FIG. 17A is a plan view of the first substrate 41 (semiconductor substrate 41) out of the two semiconductor substrates. FIG. 17B is a sectional view of the first substrate 41.

As illustrated in FIG. 17A, the entire pixel array region 111 formed on the first substrate 41 is formed as an SiGe region.

As for the pixel array region 111 formed of the SiGe region, it is possible to form the entire pixel array region 111 by the SiGe region by implanting Ge ions in a part that serves as the pixel array region 111 in the semiconductor substrate 41 which is the Si region as illustrated in FIG. 17B.

Note that in the case where the entire pixel array region 111 is formed of the SiGe region, the SiGe region may be formed such that the Ge concentration differs in the depth direction of the first substrate 41. Specifically, it is possible to form the SiGe region to have a gradient of Ge concentration depending on the substrate depth such that the Ge concentration on the light incidence surface side on which the on-chip lens 47 is formed is high and the Ge concentration decreases toward the pixel transistor formation surface as illustrated in FIG. 18.

For example, the ratio between Si and Ge can be 2:8 (Si: Ge = 2:8) and the substrate concentration can be 4E + 22 /cm³ at the part where the concentration is high on the light incidence surface side, the ratio between Si and Ge can be 8:2 (Si: Ge = 8:2) and the substrate concentration can be 1E + 22 /cm³ at the part where the concentration is low in the vicinity of the pixel transistor formation surface, and the entire pixel array region 111 can have a concentration in a range of 1E + 22 to 4E + 22 /cm³.

The control of the concentration can be performed by selecting the implantation depth through control of implantation energy at the time of ion implantation or by selecting an implantation region (a region in the plane direction) using a mask, for example. It is a matter of course that the quantum efficiency of infrared light can be further enhanced as the Ge concentration increases.

### 14. Detailed Configuration Example of Pixel Area ADC

In the case where not only the photodiode PD (N-type semiconductor region 52) but also the entire pixel array region 111 is formed of the SiGe region as illustrated in FIGS. 16 to 18, there is a concern that the dark current of the floating diffusion regions FD deteriorates. As one measure against the deterioration of the dark current of the floating diffusion region FD, there is a method of forming an Si layer on the SiGe region and causing the Si layer to serve as the floating diffusion region FD as illustrated in FIG. 11, for example.

As another measure against the deterioration of the dark current of the floating diffusion region FD, it is possible to employ a configuration of the pixel area ADC in which AD conversion portions are provided in units of pixels or in units of surrounding n × n pixels (n is an integer of equal to or greater than 1) instead of performing AD conversion in units of columns of the pixels 10 as illustrated in FIG. 1. It is possible to shorten the time during which the charges are held in the floating diffusion region FD as compared with the column ADC type in FIG. 1 by employing the configuration of the pixel area ADC and thereby to curb the degradation of the dark current of the floating diffusion region FD.

In FIGS. 19 to 20, the configuration of the light receiving element 1 in which the AD conversion portions are provided in units of pixels is described.

FIG. 19 is a block diagram illustrating a detailed configuration example of the pixel 10 with the AD conversion portion provided for each pixel.

The pixel 10 is configured of a pixel circuit 201 and an AD conversion portion (ADC) 202. In a case where the AD conversion portions are provided in units of n × n pixels rather than units of pixels, one ADC 202 is provided for n × n pixel circuits 201.

The pixel circuit 201 outputs a charge signal in accordance with the amount of received light as an analog pixel signal SIG to the ADC 202. The ADC 202 converts the analog pixel signal SIG supplied from the pixel circuit 201 into a digital signal.

The ADC 202 is configured of a comparison circuit 211 and a data storage portion 212.

The comparison circuit 211 compares a reference signal REF supplied from a DAC 241 provided as a peripheral circuit portion with the pixel signal SIG from the pixel circuit 201 and outputs an output signal VCO as a comparison result signal representing the comparison result. The comparison circuit 211 inverts the output signal VCO when the reference signal REF and the pixel signal SIG are the same (voltage).

The comparison circuit 211 is configured of a differential input circuit 221, a voltage conversion circuit 222, and a positive feedback circuit (PFB) 223, and details thereof will be described with reference to FIG. 20.

In addition to the output signal VCO input from the comparison circuit 211, a WR signal representing a pixel signal writing operation, a RD signal representing a pixel signal reading operation, and a WORD signal for controlling a reading timing of the pixel 10 during the pixel signal reading operation are supplied from the vertical drive portion 22 to the data storage portion 212. Also, a clock time code generated by a clock time code generating portion (not illustrated) as a peripheral circuit portion is supplied via a clock time code transfer portion 242 provided as a peripheral circuit portion.

The data storage portion 212 is configured of a latch control circuit 231 that controls clock time code reading operation and writing operation on the basis of the WR signal and the RD signal and a latch storage portion 232 that stores the clock time code.

The latch control circuit 231 causes the latch storage portion 232 to store the clock time code that is supplied from the clock time code transfer portion 242 when a Hi (High) output signal VCO is input from the comparison circuit 211 and that is updated every unit time in the clock time code writing operation. Also, when the reference signal REF and the pixel signal SIG become the same (voltage) and the output signal VCO supplied from the comparison circuit 211 is inverted to Lo (Low), the latch control circuit 231 stops the writing (updating) of the supplied clock time code and causes the latch storage portion 232 to hold the last clock time code stored in the latch storage portion 232. The clock time code stored in the latch storage portion 232 represents a clock time at which the pixel signal SIG becomes equal to the reference signal REF and represents the digitalized value of the amount of light.

After sweeping of the reference signal REF ends and the clock time codes are stored in the latch storage portions 232 of all the pixels 10 in the pixel array portion 21, the operation of the pixels 10 is changed from the writing operation to the reading operation.

The latch control circuit 231 outputs the clock time code (digital pixel signal SIG) stored in the latch storage portion 232 to the clock time code transfer portion 242 when the reading time of each pixel 10 itself is reached, on the basis of the WORD signal for controlling the reading timing in the clock time code reading operation. The clock time code transfer portion 242 transfers the supplied clock time code in order in the column direction (vertical direction) and supplies them to the signal processing portion 26.

### <Detailed Configuration Example of Comparison Circuit>

FIG. 20 is a circuit diagram illustrating detailed configurations of the differential input circuit 221, the voltage conversion circuit 222, and the positive feedback circuit 223 configuring the comparison circuit 211, and the pixel circuit 201.

Note that FIG. 20 illustrates a circuit corresponding to one tap in the pixel 10 configured of two taps due to limitation of the space.

The differential input circuit 221 compares the pixel signal SIG of one tap output from the pixel circuit 201 in the pixel 10 with the reference signal REF output from the DAC 241 and outputs a predetermined signal (current) when the pixel signal SIG is higher than the reference signal REF.

The differential input circuit 221 is configured of transistors 281 and 282 that serve as a differential pair, transistors 283 and 284 that configure a current mirror, a transistor 285 that is a constant current source for supplying a current IB in accordance with an input bias current Vb, and a transistor 286 that outputs an output signal HVO of the differential input circuit 221.

The transistors 281, 282, and 285 are configured of negative channel MOS (NMOS) transistors while the transistors 283, 284, and 286 are configured of positive channel MOS (PMOS) transistors.

The reference signal REF output from the DAC 241 is input to the gate of the transistor 281 configuring the differential pair, and the pixel signal SIG output from the pixel circuit 201 in the pixel 10 is input to the gate of the transistor 282 out of the transistors 281 and 282. The sources of the transistors 281 and 282 are connected to the drain of the transistor 285, and the source of the transistor 285 is connected to a predetermined voltage VSS (VSS < VDD2 < VDD1).

The drain of the transistor 281 is connected to the gates of the transistors 283 and 284 configuring the current mirror circuit and the drain of the transistor 283, and the drain of the transistor 282 is connected to the drain of the transistor 284 and the gate of the transistor 286. The sources of the transistors 283, 284, and 286 are connected to a first power source voltage VDD1.

The voltage conversion circuit 222 is configured of, for example, an NMOS-type transistor 291. The drain of the transistor 291 is connected to the drain of the transistor 286 in the differential input circuit 221, the source of the transistor 291 is connected to a predetermined connection point in the positive feedback circuit 223, and the gate of the transistor 286 is connected to a bias voltage VBIAS.

The transistors 281 to 286 configuring the differential input circuit 221 are circuits that operate at high voltages up to the first power source voltage VDD1, and the positive feedback circuit 223 is a circuit that operates at a second power source voltage VDD2 that is lower than the first power source voltage VDD1. The voltage conversion circuit 222 converts an output signal HVO input from the differential input circuit 221 into a signal (conversion signal) LVI at a low voltage at which the positive feedback circuit 223 can operate and supplies the signal (conversion signal) LVI to the positive feedback circuit 223.

The bias voltage VBIAS may be any voltage as long as it is converted into a voltage at which each of transistors 301 to 307 in the positive feedback circuit 223 operating at a low voltage is not broken. For example, the bias voltage VBIAS can be the same voltage as the second power source voltage VDD2 (VBIAS = VDD2) of the positive feedback circuit 223.

The positive feedback circuit 223 outputs a comparison result signal that is inverted when the pixel signal SIG is higher than the reference signal REF on the basis of the conversion signal LVI obtained by converting the output signal HVO from the differential input circuit 221 into a signal corresponding to the second power source voltage VDD2. Also, the positive feedback circuit 223 increases the transition speed when the output signal VCO to be output as the comparison result signal is inverted.

The positive feedback circuit 223 is configured of seven transistors 301 to 307. The transistors 301, 302, 304, and 306 are configured of PMOS transistors while the transistors 303, 305, and 307 are configured of NMOS transistors.

The source of the transistor 291 which is an output terminal of the voltage conversion circuit 222 is connected to the drains of the transistors 302 and 303 and the gates of the transistors 304 and 305. The source of the transistor 301 is connected to the second power source voltage VDD2, the drain of the transistor 301 is connected to the source of the transistor 302, and the gate of the transistor 302 is connected to the drains of the transistors 304 and 305 which also serve as output terminals of the positive feedback circuit 223. The sources of the transistors 303 and 305 are connected to a predetermined voltage VSS. An initialization signal INI is supplied to the gates of the transistors 301 and 303.

The transistors 304 to 307 configure a two-input NOR circuit, and the connection point between the drains of the transistors 304 and 305 serves as an output terminal from which the comparison circuit 211 outputs the output signal VCO.

A control signal TERM which is a second input rather than the conversion signal LVI which is a first input is supplied to the gate of the transistor 306 configured of the PMOS transistor and the gate of the transistor 307 configured of the NMOS transistor.

The source of the transistor 306 is connected to the second power source voltage VDD2, and the drain of the transistor 306 is connected to the source of the transistor 304. The drain of the transistor 307 is connected to the output terminal of the comparison circuit 211, and the source of the transistor 307 is connected to the predetermined voltage VSS.

Operations of the comparison circuit 211 configured as described above will be described.

First, the reference signal REF is set to a higher voltage than the pixel signals SIG of all the pixels 10, the initialization signal INI is set to Hi, and the comparison circuit 211 is initialized.

More specifically, the reference signal REF is applied to the gate of the transistor 281, and the pixel signal SIG is applied to the gate of the transistor 282. When the voltage of the reference signal REF is a voltage that is higher than the voltage of the pixel signal SIG, a most part of a current output from the transistor 285 that serves as a current source flows through the transistor 283 connected to the diode via the transistor 281. The channel resistance of the transistor 284 having a gate shared with the transistor 283 becomes sufficiently low, the gate of the transistor 286 is kept substantially at the level of the first power source voltage VDD1, and the transistor 286 is blocked. Therefore, the positive feedback circuit 223 that serves as a charging circuit does not charge the conversion signal LVI even if the transistor 291 of the voltage conversion circuit 222 is conductive. On the other hand, since the Hi signal as the initialization signal INI is supplied, the transistor 303 is conductive, and the positive feedback circuit 223 discharges the conversion signal LVI. Also, since the transistor 301 is blocked, the positive feedback circuit 223 does not charge the conversion signal LVI via the transistor 302. As a result, the conversion signal LVI is discharged up to the predetermined voltage VSS level, the positive feedback circuit 223 outputs the Hi output signal VCO through the transistors 304 and 305 configuring the NOR circuit, and the comparison circuit 211 is initialized.

After the initialization, the initialization signal INI is set to Lo, and sweeping of the reference signal REF is started.

During a period when the reference signal REF has a higher voltage than the pixel signal SIG, the transistor 286 is turned off and thus blocked, the output signal VCO becomes a Hi signal, and the transistor 302 is thus turned off and blocked. The transistor 303 is also blocked since the initialization signal INI is Lo. The conversion signal LVI keeps the predetermined voltage VSS in a high impedance state, and the Hi output signal VCO is output.

If the reference signal REF becomes lower than the pixel signal SIG, the output current of the transistor 285 of the current source does not flow through the transistor 281, gate potentials of the transistors 283 and 284 increase, and the channel resistance of the transistor 284 becomes high. Then, the current flowing via the transistor 282 causes a voltage drop and lowers the gate potential of the transistor 286, and the transistor 291 becomes conductive. The output signal HVO output from the transistor 286 is converted into the conversion signal LVI by the transistor 291 of the voltage conversion circuit 222 and is then supplied to the positive feedback circuit 223. The positive feedback circuit 223 that serves as the charging circuit charges the conversion signal LVI and causes the potential to approach the second power source voltage VDD2 from the low voltage VSS.

If the voltage of the conversion signal LVI exceeds a threshold voltage of an inverter configured by the transistors 304 and 305, then the output signal VCO becomes Lo, and the transistor 302 becomes conductive. The transistor 301 is also conductive since the Lo initialization signal INI is applied thereto, and the positive feedback circuit 223 rapidly charges the conversion signal LVI via the transistors 301 and 302 and raises the potential to the second power source voltage VDD2 at once.

Since the bias voltage VBIAS is applied to the gate of the transistor 291 of the voltage conversion circuit 222, the transistor 291 is blocked when the voltage of the conversion signal LVI reaches a voltage value that is lower than the bias voltage VBIAS by a transistor threshold value. The conversion signal LVI is not charged any more if the transistor 286 is still conductive, and the voltage conversion circuit 222 functions as a voltage clamp circuit as well.

The charging of the conversion signal LVI through conduction of the transistor 302 is originally triggered by a rise of the conversion signal LVI to the inverter threshold value and is a positive feedback operation that accelerates the motion. Since the number of circuits operating at the same time in parallel in the light receiving element 1 is huge, the transistor 285 which is a current source of the differential input circuit 221 is adapted such that a current per circuit is set to a considerably low current. Moreover, the reference signal REF is considerably mildly swept since the voltage changing in a unit time when the clock time code is switched serves as an LSB step for AD conversion. Therefore, a change in gate potential of the transistor 286 is also mild, and a change in output current of the transistor 286 driven by the gate potential is also mild. However, the output signal VCO can sufficiently rapidly transition by applying positive feedback from a later stage to the conversion signal LVI charged with the output current. It is desirable that the transition time of the output signal VCO be a fraction of the unit time of the clock time code and is equal to or less than 1 ns in a typical example. The comparison circuit 211 can achieve the output transition time merely by setting a low current, for example, 0.1 µA in the transistor 285 of the current source.

If the control signal TERM which is the second input of the NOR circuit is set to Hi, it is possible to set the output signal VCO to Lo regardless of the state of the differential input circuit 221.

If the voltage of the pixel signal SIG becomes lower than a final voltage of the reference signal REF due to higher luminance than expected, for example, then the comparison period is ended with the output signal VCO of the comparison circuit 211 kept Hi, the data storage portion 212 controlled by the output signal VCO cannot fix a value, and the AD conversion function is lost. In order to prevent occurrence of such a state, it is possible to forcibly invert the output signal VCO which has not yet been inverted to Lo, by inputting a control signal TERM of a Hi pulse at the end of the sweeping of the reference signal REF. Since the data storage portion 212 stores (latches) the clock time code immediately before the forced inversion, in a case where the configuration of FIG. 20 is adopted, the ADC 202 functions as an AD converter with a clamped output value in response to a luminance input of equal to or greater than a specific value, as a result.

If the bias voltage VBIAS is controlled to the Lo level, the transistor 291 is blocked, and the initialization signal INI is set to Hi, then the output signal VCO becomes Hi regardless of the state of the differential input circuit 221. Therefore, the output signal VCO can be set to an arbitrary value regardless of the states of the differential input circuit 221 and the pixel circuit 201 and the DAC 241 corresponding to the former stages thereof, by combining the forced Hi output of the output signal VCO and the forced LO output based on the aforementioned control signal TERM. With this function, it is possible to test the circuits in the later stages of the pixel 10 merely using electrical signal inputs without depending on optical inputs to the light receiving element 1, for example.

FIG. 21 is a circuit diagram illustrating connection between an output of each tap in the pixel circuit 201 and the differential input circuit 221 of the comparison circuit 211.

As illustrated in FIG. 21, the differential input circuit 221 of the comparison circuit 211 illustrated in FIG. 20 is connected to the output destination of each tap of the pixel circuit 201.

The pixel circuit 201 in FIG. 20 is equivalent to the pixel circuit 201 in FIG. 21 and is similar to the circuit configuration of the pixel 10 illustrated in FIG. 3.

In a case where the configuration of the pixel area ADC is employed, the number of circuits in units of pixels or in units of n × n pixels (n is an integer of equal to or greater than 1) increases, and the light receiving element 1 is thus configured of the laminated structure illustrated in FIG. 12B. In this case, it is possible to dispose the pixel circuit 201 and the transistor 281, 282, and 285 of the differential input circuit 221 on the first substrate 41 and to dispose the other circuits on the second substrate 141 as illustrated in FIG. 21, for example. The first substrate 41 and the second substrate 141 are electrically connected through Cu-Cu bonding. Note that the circuit arrangement of the first substrate 41 and the second substrate 141 is not limited to this example.

As described above, it is possible to reduce the time during which the charges are accumulated in the floating diffusion region FD as compared with the column ADC in FIG. 1 by employing the configuration of the pixel area ADC as a measure against deterioration of the dark current of the floating diffusion region FD in the case where the entire pixel array region 111 is formed of the SiGe region and thereby to curb the deterioration of the dark current of the floating diffusion region FD.

### 15. Sectional View According to Second Configuration Example of Pixel

FIG. 22 is a sectional view illustrating a second configuration example of the pixels 10 disposed in the pixel array portion 21.

In FIG. 22, parts corresponding to those in the first configuration example illustrated in FIG. 2 are denoted by the same reference signs, and description of the parts will be appropriately omitted.

FIG. 22 is a sectional view of a pixel structure of the memory MEM holding-type pixel 10 illustrated in FIG. 5 and illustrates a sectional view in the case of the configuration of the laminated structure of the two substrates illustrated in FIG. 12B.

However, the metal film M of the wiring layer 151 on the side of the first substrate 41 and the metal film M of the wiring layer 161 of the second substrate 141 are electrically connected to each other with the TSV 171 and the TSV 172 in the sectional view of the laminated structure illustrated in FIG. 13, while the metal films M are electrically connected to each other through Cu-Cu bonding in FIG. 22.

Specifically, the wiring layer 151 of the first substrate 41 includes a first metal film M21, a second metal film M22, and an insulating layer 153 while the wiring layer 161 of the second substrate 141 includes a first metal film M31, a second metal film M32, and an insulating layer 173. The wiring layer 151 of the first substrate 41 and the wiring layer 161 of the second substrate 141 are electrically connected at the Cu films formed at parts of bonding surfaces illustrated by the dashed lines.

In the second configuration example in FIG. 22, the entire pixel array region 111 of the first substrate 41 described above with reference to FIG. 17 is formed of the SiGe region. In other words, the P-type semiconductor region 51 and the N-type semiconductor region 52 are formed of SiGe regions. In this manner, quantum efficiency with respect to infrared light is improved.

The pixel transistor formation surface of the first substrate 41 will be described with reference to FIG. 23.

FIG. 23 is a sectional view illustrating the vicinity of the pixel transistor of the first substrate 41 in FIG. 22 in an enlarged manner.

The first transfer transistors TRGa1 and TRGa2, the second transfer transistors TRGb1 and TRGb2 and the memories MEM1 and MEM2 are formed for each pixel 10 on the interface of the first substrate 41 on the side of the wiring layer 151.

An oxide film 351 is formed on the interface of the first substrate 41 on the side of the wiring layer 151 to have a film thickness of about 10 to 100 nm, for example. The oxide film 351 is formed by forming a silicon film on the surface of the first substrate 41 through epitaxial growth and performing heat treatment thereon. The oxide film 351 also functions as a gate insulating film of each of the first transfer transistors TRGa and the second transfer transistor TRGb.

Since it is difficult to form, with the SiGe region, a satisfactory oxide film as compared with Si, the dark currents generated from the transfer transistor TRG and the memory MEM increase. Since the light receiving element 1 of the indirect ToF scheme repeats the operations of alternately turning on and off the transfer transistors TRG between two or more taps, it is not possible to ignore the dark current generated due to the gates when the transfer transistors TRG are turned on.

With the oxide film 351 with the film thickness of about 10 to 100 nm, it is possible to reduce the dark current due to an interface state. It is thus possible to curb the dark current while enhancing quantum efficiency according to the second configuration example. Similar effects can be obtained even in a case where the Ge region is formed instead of the SiGe region.

In a case where the pixel 10 does not have a laminated structure of two substrates and all pixel transistors are formed on the surface of the one semiconductor substrate 41 on one side as in FIG. 2, it is possible to reduce reset noise from the amplification transistor AMP as well by forming the oxide film 351.

### 16. Sectional View According to Third Configuration Example of Pixel

FIG. 24 is a sectional view illustrating a third configuration example of the pixels 10 disposed in the pixel array portion 21.

Parts corresponding to those in the first configuration example illustrated in FIG. 2 and those in the second configuration example illustrated in FIG. 22 are denoted by the same reference signs, and description of the parts will be appropriately omitted.

FIG. 24 is a sectional view of the pixels 10 in a case where the light receiving element 1 is configured of a laminated structure of two substrate and is a sectional view in a case where connection is established through Cu-Cu bonding similarly to the second configuration example illustrated in FIG. 22. Also, the entire pixel array region 111 of the first substrate 41 is formed of the SiGe region similarly to the second configuration example illustrated in FIG. 22.

In a case where the floating diffusion regions FD1 and FD2 are formed of SiGe regions, there is a problem that the dark current generated from the floating diffusion regions FD increases as described above. Therefore, the floating diffusion regions FD1 and FD2 formed in the first substrate 41 are formed to have small volumes in order to minimize influences of the dark current.

However, the capacities of the floating diffusion regions FD1 and FD2 decrease, and it is not possible to accumulate sufficient charges, merely by reducing the volumes of the floating diffusion regions FD1 and FD2.

Thus, in the third configuration example in FIG. 24, a metal insulator metal (MIM) capacitor element 371 is formed in the wiring layer 151 of the first substrate 41 and is constantly connected to the floating diffusion regions FD, and the capacity of the floating diffusion regions FD is thus increased. Specifically, an MIM capacitor element 371-1 is connected to the floating diffusion region FD1, and a MIM capacitor element 371-2 is connected to the floating diffusion region FD2. The MIM capacitor elements 371 are realized in small installation areas by using U-shaped three-dimensional structures.

According to the pixel 10 in the third configuration example in FIG. 24, it is possible to compensate for the insufficient capacities of the floating diffusion regions FD formed to have volumes reduced to curb generation of the dark current with the MIM capacitor element 371. In this manner, it is possible to realize curbing of the dark current and securing of the capacity in a case where the SiGe region is used at the same time. In other words, it is possible to curb the dark current while enhancing quantum efficiency in response to infrared light according to the third configuration example.

Note that although the example of the MIM capacitor element has been described as an additional capacitor element connected to the floating diffusion regions FD in the example in FIG. 24, the capacitor element is not limited to the MIM capacitor element. For example, an additional capacitor including a metal oxide metal (MOM) capacitor element, a Poly-Poly capacitor element (the capacitor element in which both facing electrodes are formed of polysilicon), a parasitic capacitor formed of wiring, or the like may be used.

Also, in a case where the pixel 10 has a pixel structure including the memories MEM1 and MEM2 as in the second configuration example illustrated in FIG. 22, it is possible to employ a configuration in which an additional capacitor element is connected not only to the floating diffusion regions FD but also to the memories MEM.

Although the additional capacitor element connected to the floating diffusion regions FD or the memories MEM may be formed in the wiring layer 151 of the first substrate 41 in the example in FIG. 24, the additional capacitor element may be formed in the wiring layer 161 of the second substrate 14.

Although the light shielding member 63 and the wiring capacitor 64 in the first configuration example in FIG. 2 are omitted in the example in FIG. 24, the light shielding member 63 and the wiring capacitor 64 may be formed.

### 17. Configuration Example of IR Imaging Sensor

The aforementioned structure of the light receiving element 1 with quantum efficiency of near-infrared light improved by forming the photodiode PD or the pixel array region 111 by the SiGe region or the Ge region is not limited to the distance measurement sensor that outputs distance measurement information based on the indirect ToF scheme and can be employed in another sensor that receives infrared light.

Hereinafter, examples of an IR imaging sensor that receives infrared light and generates an IR image and an RGBIR imaging sensor that receives infrared light and RGB light will be described as examples of other sensors in which a part of the semiconductor substrate is formed of the SiGe region or the Ge region.

Also, examples of a distance measurement sensor based on the direct ToF scheme using SPAD pixels and a ToF sensor based on a current assisted photonic demodulator (CAPD) scheme will be described as other examples of the distance measurement sensor that receives infrared light and outputs distance measurement information.

FIG. 25 illustrates a circuit configuration of the pixel 10 in a case where the light receiving element 1 is configured as an IR imaging sensor that generates and outputs an IR image.

In a case where the light receiving element 1 is a ToF sensor, the light receiving element 1 distributes charges generated by the photodiode PD into two floating diffusion regions FD1 and FD2 and accumulates the charges therein, and the pixel 10 thus includes two transfer transistors TRG, two floating diffusion regions FD, two additional capacitors FDL, two switching transistors FDG, two amplification transistors AMP, two reset transistors RST, and two selection transistors SEL.

In a case where the light receiving element 1 is an IR imaging sensor, the number of charge holding portions in which charges generated by the photodiode PD are temporarily held may be one, and the number of transfer transistors TRG, the number of floating diffusion regions FD, the number of additional capacitors FDL, the number of switching transistors FDG, the number of amplification transistors AMP, the number of reset transistors RST, and the number of selection transistors SEL are thus also set to be one.

In other words, in a case where the light receiving element 1 is an IR imaging sensor, the pixel 10 has a configuration equivalent to that obtained by omitting the transfer transistor TRG2, the switching transistor FDG2, the reset transistor RST2, the amplification transistor AMP2, and the selection transistor SEL2 from the circuit configuration illustrated in FIG. 3 as illustrated in FIG. 25. The floating diffusion region FD2 and the vertical signal line 29B are also omitted.

FIG. 26 is a sectional view illustrating a configuration example of the pixel 10 in a case where the light receiving element 1 is configured as an IR imaging sensor.

A difference between a case where the light receiving element 1 is configured as an IR imaging sensor and a case where the light receiving element 1 is configured as a ToF sensor is whether or not the floating diffusion region FD2 formed on the front surface side of the semiconductor substrate 41 and a pixel transistor are present as described in FIG. 25. Therefore, the configuration of the multilayer wiring layer 42 formed on the front surface side of the semiconductor substrate 41 is different from that in FIG. 2. Also, the floating diffusion region FD2 is omitted. The other configurations in FIG. 26 are similar to those in FIG. 2.

It is possible to enhance quantum efficiency of near-infrared light by forming the photodiode PD by the SiGe region or the Ge region in FIG. 26 as well. Not only the aforementioned first configuration example in FIG. 2 but also the configuration of the pixel area ADC, the second configuration example in FIG. 22, and the third configuration example in FIG. 24 are similarly applied to the IR imaging sensor. Also, it is possible to form not only the photodiode PD but also the entire pixel array region 111 by the SiGe region or the Ge region as described in FIGS. 16 to 18.

### 18. Configuration Example of RGBIR Imaging Sensor

Although the light receiving element 1 having the pixel structure in FIG. 26 is a sensor in which all the pixels 10 receive infrared light, the light receiving element 1 can also be applied to an RGBIR imaging sensor that receives infrared light and RGB light.

In a case where the light receiving element 1 is configured as an RGBIR imaging sensor that receives infrared light and RGB light, 2 × 2 pixel arrangement illustrated in FIG. 27, for example, is repeatedly aligned in the row direction and the column direction.

FIG. 27 illustrates an example of arrangement of pixels in a case where the light receiving element 1 is configured as an RGBIR imaging sensor that receives infrared rays and RGB lays.

In a case where the light receiving element 1 is configured as an RGBIR imaging sensor, an R pixel that receives light of R (red), a B pixel that receives light of B (blue), a G pixel that receives light of G (green), and an IR pixel that receives light of IR (infrared) are allocated to 4 pixels in 2 × 2, as illustrated in FIG. 27.

Which of the R pixel, the B pixel, the G pixel, and the IR pixel each pixel 10 corresponds to is determined by a color filter layer inserted between the flattened film 46 and the on-chip lens 47 in FIG. 26 in the RGBIR imaging sensor.

FIG. 28 is a sectional view illustrating the color filter layer inserted between the flattened film 46 and the on-chip lens 47 in a case where the light receiving element 1 is configured as the RGBIR imaging sensor.

In FIG. 28, the B pixel, the G pixel, the R pixel, and the IR pixel are aligned in order from the left to the right.

A first color filter layer 381 and a second color filter layer 382 are inserted between the flattened film 46 (not illustrated in FIG. 28) and the on-chip lens 47.

In the B pixel, a B filter that allows B light to be transmitted therethrough is disposed in the first color filter layer 381, and an IR cut filter that blocks IR light is disposed in the second color filter layer 382. In this manner, only the B light is transmitted through the first color filter layer 381 and the second color filter layer 382 and is then incident on the photodiode PD.

In the G pixel, a G filter that allows G light to be transmitted therethrough is disposed in the first color filter layer 381, and the IR cut filter that blocks IR light is disposed in the second color filter layer 382. In this manner, only the G light is transmitted through the first color filter layer 381 and the second color filter layer 382 and is then incident on the photodiode PD.

In the R pixel, an R filter that allows R light to be transmitted therethrough is disposed in the first color filter layer 381, and the IR cut filter that blocks the IR light is disposed in the second color filter layer 382. In this manner, only the R light is transmitted through the first color filter layer 381 and the second color filter layer 382 and is then incident on the photodiode PD.

In the IR pixel, an R filter that allows R light to be transmitted therethrough is disposed in the first color filter layer 381, and a B filter that allows B light to be transmitted therethrough is disposed in the second color filter layer 382. In this manner, light with a wavelength other than the wavelength from B to R is transmitted, and the IR light is thus transmitted through the first color filter layer 381 and the second color filter layer 382 and is then incident on the photodiode PD.

In the case where the light receiving element 1 is configured as the RGBIR imaging sensor, the photodiode PD of the IR pixel is formed of the aforementioned SiGe region or Ge region, and the R pixel, the G pixel, and the photodiode PD of the R pixel are formed of the Si regions.

It is possible to enhance quantum efficiency of near-infrared light by forming the photodiode PD of the IR pixel by the SiGe region or the Ge region even in the case where the light receiving element 1 is configured as the RGBIR imaging sensor as well. Not only the aforementioned first configuration example in FIG. 2 but also the configuration of the pixel area ADC, the second configuration example in FIG. 22, and the third configuration example in FIG. 24 can also be employed for the RGBIR imaging sensor. Also, it is possible to form not only the photodiode PD but also the entire pixel array region 111 by the SiGe region or the Ge region as described in FIGS. 16 to 18.

### 19. Configuration Example of SPAD Pixel

Next, an example in which the aforementioned structure of the pixel 10 is applied to a distance measurement sensor of the direct ToF scheme using SPAD pixels will be described.

ToF sensors include an indirect ToF sensor and a direct ToF sensor. The indirect ToF sensor is a scheme in which a flight time until reflected light is received after irradiation light is emitted is detected as a phase difference and the distance to an object is thus calculated, while the direct ToF sensor is based on a scheme in which a flight time until reflection light is received after irradiation light is emitted is directly measured and the distance to an object is calculated.

In the light receiving element 1 that directly measures the flight time, a single photon avalanche diode (SPAD), for example, is used as the photoelectric conversion element of each pixel 10.

FIG. 29 illustrates a circuit configuration example of a SPAD pixel using a SPAD as the photoelectric conversion element of the pixel 10.

The pixel 10 in FIG. 29 includes a SPAD 401 and a reading circuit 402 configured of a transistor 411 and an inverter 412. Additionally, the pixel 10 also includes a switch 413. The transistor 411 is configured of a P-type MOS transistor.

The cathode of the SPAD 401 is connected to the drain of the transistor 411 and is also connected to an input terminal of the inverter 412 and one end of the switch 413. The anode of the SPAD 401 is connected to the power source voltage VA (hereinafter, also referred to as an anode voltage VA).

The SPAD 401 is a photodiode (single-photon avalanche diode) that performs avalanche-amplification on generated electrons and outputs a signal of a cathode voltage VS when incident light is incident. The power source voltage VA supplied to the anode of the SPAD 401 is a negative bias (negative potential) of about -20 V, for example.

The transistor 411 is a constant current source that operates in a saturated region and performs passive quench by working as a quenching resistor. The transistor 411 has a source connected to the power source voltage VE and a drain connected to the cathode of the SPAD 401, the input terminal of the inverter 412, and one end of the switch 413. In this manner, the power source voltage VE is also supplied to the cathode of the SPAD 401. It is also possible to use a pull-up resistor instead of the transistor 411 connected in series to the SPAD 401.

In order to detect photons with sufficient efficiency, a larger voltage (excess bias (ExcessBias)) than the breakdown voltage VBD of the SPAD 401 is applied to the SPAD 401. If the breakdown voltage VBD of the SPAD 401 is 20 V, and a voltage that is greater than that by 3 V is applied, for example, the power source voltage VE supplied to the source of the transistor 411 is 3 V.

Note that the breakdown voltage VBD of the SPAD 401 significantly changes depending on the temperature and the like. Therefore, the application voltage applied to the SPAD 401 is controlled (adjusted) in accordance with a change in breakdown voltage VBD. If the power source voltage VE is a fixed voltage, for example, the anode voltage VA is controlled (adjusted).

The switch 413 includes one of both ends connected to the cathode of the SPAD 401, the input terminal of the inverter 412, and the drain of the transistor 411 and the other end connected to the ground (GND). The switch 413 is configured of, for example, an N-type MOS transistor and is turned on and off in accordance with a gating control signal VG supplied from the vertical drive portion 22.

The vertical drive portion 22 sets each pixel 10 in the pixel array portion 21 to an active pixel or a non-active pixel by supplying High or Low gating control signal VG to the switch 413 of each pixel 10 and turning on or off the switch 413. The active pixel is a pixel that detects incidence of photons, while the non-active pixel is a pixel that does not detect incidence of photons. If the switch 413 is turned on in accordance with the gating control signal VG, and the cathode of the SPAD 401 is controlled by the ground, then the pixel 10 becomes the non-active pixel.

Operations performed in a case where the pixel 10 in FIG. 29 is set to the active pixel will be described with reference to FIG. 30.

FIG. 30 is a graph illustrating a change in cathode voltage VS of the SPAD 401 and a pixel signal PFout in accordance with incidence of photons.

First, in the case where the pixel 10 is the active pixel, the switch 413 is set to be off as described above.

A power source voltage VE (3 V, for example) is supplied to the cathode of the SPAD 401, the power source voltage VA (-20 V, for example) is supplied to the anode, and the SPAD 401 is thus set to a geiger mode by applying a reverse voltage that is greater than the breakdown voltage VBD (= 20 V) to the SPAD 401. In this state, the cathode voltage VS of the SPAD 401 is the same as the power source voltage VE at the clock time t0 in FIG. 30, for example.

If photons are incident on the SPAD 401 set in the geiger mode, avalanche multiplication occurs, and a current flows through the SPAD 401.

If avalanche multiplication occurs at the clock time t1 in FIG. 30, and a current flows through the SPAD 401, then the current also flows the transistor 411 by the current flowing through the SPAD 401 at and after the clock time t1, and a voltage drop occurs due to a resistance component of the transistor 411.

If the cathode voltage VS of the SPAD 401 drops below 0 V at the clock time t2, a state in which the voltage between the anode and the cathode of the SPAD 401 is lower than the breakdown voltage VBD is achieved, and the avalanche amplification is thus stopped. Here, the operation of stopping the avalanche amplification by causing a voltage drop by the current generated through the avalanche amplification flowing through the transistor 411 and achieving the state where the cathode voltage VS is lower than the breakdown voltage VBD with the occurring voltage drop is a quench operation.

Once the avalanche amplification stops, the current flowing through the resistor of the transistor 411 gradually decreases, the cathode voltage VS returns to the original power source voltage VE again at the clock time t4, and a state in which the next new photons can be detected is achieved (recharge operation).

The inverter 412 outputs an Lo pixel signal PFout when the cathode voltage VS that is an input voltage is equal to or greater than a predetermined threshold voltage Vth, and the inverter 412 outputs a Hi pixel signal PFout when the cathode voltage VS is less than the predetermined threshold voltage Vth. Therefore, if photons are incident on the SPAD 401, avalanche multiplication occurs, and the cathode voltage VS decreases and drops below the threshold voltage Vth, then the pixel signal PFout is inverted from the low level to the high level. On the other hand, if the avalanche multiplication of the SPAD 401 converges, and the cathode voltage VS rises and increases to be equal to or greater than the threshold voltage Vth, then the pixel signal PFout is inverted from the high level to the low level.

Note that in a case where the pixel 10 is set to a non-active pixel, the switch 413 is turned on. If the switch 413 is turned on, then the cathode voltage VS of the SPAD 401 becomes 0 V. As a result, since the voltage between the anode and the cathode of the SPAD 401 becomes equal to or less than the breakdown voltage VBD, a state in which entrance of photons to the SPAD 401 is not responded is achieved.

FIG. 31 is a sectional view illustrating a configuration example in a case where the pixel 10 is a SPAD pixel.

In FIG. 31, parts corresponding to those in the aforementioned other configuration examples are denoted by the same reference signs, and description of the parts will be appropriately omitted.

In FIG. 31, the inter-pixel separation portion 61 formed to the predetermined depth in the substrate depth direction from the rear surface side (the side of the on-chip lens 47) of the semiconductor substrate 41 at the pixel boundary portion 44 in FIG. 2 is changed with an inter-pixel separation portion 61′ penetrating through the semiconductor substrate 41.

The pixel region inside the inter-pixel separation portion 61′ in the semiconductor substrate 41 includes an N well region 441, a P-type diffusion layer 442, an N-type diffusion layer 443, a hole accumulation layer 444, and a high-concentration P-type diffusion layer 445. Also, a depletion layer formed in a region where the P-type diffusion layer 442 and the N-type diffusion layer 443 are connected forms an avalanche multiplication region 446.

The N well region 441 is formed by impurity concentration in the semiconductor substrate 41 being controlled to an N type and forms an electric field that transfers electrons generated through photoelectric conversion in the pixel 10 to the avalanche multiplication region 446. The N well region 441 is formed of an SiGe region or a Ge region.

The P-type diffusion layer 442 is a high-concentration P-type diffusion layer (P+) formed over substantially the entire surface of the pixel region in the plane direction. The N-type diffusion layer 443 is a high-concentration N-type diffusion layer (N+) formed over substantially the entire surface of the pixel region similarly to the P-type diffusion layer 442 in the vicinity of the surface of the semiconductor substrate 41. The N-type diffusion layer 443 is a contact layer that is connected to a contact electrode 451 as a cathode electrode for supplying a negative voltage for forming the avalanche multiplication region 446, and a part thereof has a projecting shape formed up to the contact electrode 451 on the surface of the semiconductor substrate 41. The power source voltage VE is applied from the contact electrode 451 to the N-type diffusion layer 443.

The hole accumulation layer 444 is a P-type diffusion layer (P) formed to surround the side surface and the bottom surface of the N well region 441 and accumulates holes. Also, the hole accumulation layer 444 is connected to a high-concentration P-type diffusion layer 445 that is electrically connected to a contact electrode 452 that serves as an anode electrode of the SPAD 401.

The high-concentration P-type diffusion layer 445 is a high-concentration P-type diffusion layer (P++) formed to surround the outer circumference of the N well region 441 in the plane direction in the vicinity of the surface of the semiconductor substrate 41 and configures a contact layer to electrically connect the hole accumulation layer 444 and the contact electrode 452 of the SPAD 401. The power source voltage VA is applied from the contact electrode 452 to the high-concentration P-type diffusion layer 445.

Note that a P well region in which impurity concentration in the semiconductor substrate 41 is controlled to the P type may be formed instead of the N well region 441. In a case where the P well region is formed instead of the N well region 441, the voltage applied to the N-type diffusion layer 443 becomes the power source voltage VA, and the voltage applied to the high-concentration P-type diffusion layer 445 becomes the power source voltage VE.

In the multilayer wiring layer 42, contact electrodes 451 and 452, metal wirings 453 and 454, contact electrodes 455 and 456, and metal pads 457 and 458 are formed.

Also, the multilayer wiring layer 42 is attached to a wiring layer 450 (hereinafter, referred to as a logic wiring layer 450) of the logic circuit substrate where the logic circuit is formed. The aforementioned reading circuit 402, the MOS transistor that serves as the switch 413, and the like are formed on the logic circuit substrate.

The contact electrode 451 connects the N-type diffusion layer 443 to the metal wiring 453, and the contact electrode 452 connects the high-concentration P-type diffusion layer 445 to the metal wiring 454.

The metal wiring 453 is formed to be wider than the avalanche multiplication region 446 to cover at least the avalanche multiplication region 446 in a plan view as illustrated in FIG. 31. Also, the metal wiring 453 causes light transmitted through the semiconductor substrate 41 to be reflected by the semiconductor substrate 41.

The metal wiring 454 is formed to overlap the high-concentration P-type diffusion layer 445 at the outer circumference of the metal wiring 453 in a plan view as illustrated in FIG. 31.

The contact electrode 455 connects the metal wiring 453 to the metal pad 457, and the contact electrode 456 connects the metal wiring 454 to the metal pad 458.

The metal pads 457 and 458 are electrically and mechanically connected through metal bonding of metal (Cu) forming each of the metal pads 471 and 472 formed in the logic wiring layer 450.

In the logic wiring layer 450, electrode pads 461 and 462, contact electrodes 463 to 466, an insulating layer 469, and metal pads 471 and 472 are formed.

Each of the electrode pads 461 and 462 is used for connection to the logic circuit substrate (not illustrated), and the insulating layer 469 establishes insulation between the electrode pads 461 and 462.

The contact electrodes 463 and 464 connect the electrode pad 461 to the metal pad 471, and the contact electrodes 465 and 466 connect the electrode pad 462 to the metal pad 472.

The metal pad 471 is bonded to the metal pad 457, and the metal pad 472 is bonded to the metal pad 458.

With such a wiring structure, the electrode pad 461 is connected to the N-type diffusion layer 443 via the contact electrodes 463 and 464, the metal pad 471, the metal pad 457, the contact electrode 455, the metal wiring 453, and the contact electrode 451, for example. Therefore, it is possible to supply the power source voltage VE applied to the N-type diffusion layer 443 from the electrode pad 461 of the logic circuit substrate in the pixel 10 in FIG. 31.

Also, the electrode pad 462 is connected to the high-concentration P-type diffusion layer 445 via the contact electrodes 465 and 466, the metal pad 472, the metal pad 458, the contact electrode 456, the metal wiring 454, and the contact electrode 452. It is thus possible to supply the anode voltage VA applied to the hole accumulation layer 444 from the electrode pad 462 of the logic circuit substrate in the pixel 10 in FIG. 31.

It is possible to enhance quantum efficiency of infrared light and to improve sensor sensitivity by forming at least the N well region 441 by the SiGe region or the Ge region in the pixel 10 as the SPAD pixel configured as described above. Not only the N well region 441 but also the hole accumulation layer 444 may also be formed of an SiGe region or a Ge region.

### 20. Configuration Example of CAPD Pixel

Next, an example in which the aforementioned structure of the light receiving element 1 is applied to a ToF sensor of the CAPD scheme will be described.

The pixel 10 described in FIGS. 2 and 3 and the like has a configuration of a ToF sensor called a gate scheme in which charges generated by the photodiode PD are sorted to two gates (transfer transistors TRG).

On the other hand, there is a ToF sensor called a CAPD scheme in which a voltage is applied directly to the semiconductor substrate 41 of the ToF sensor to generate a current in the substrate, and photoelectrically converted charges are sorted by modulating a photoelectric conversion region in a wide range in the substrate at a high speed.

FIG. 32 illustrates a circuit configuration example in a case where the pixel 10 is a CAPD pixel employing the CAPD scheme.

The pixel 10 in FIG. 32 includes signal extracting portions 765-1 and 765-2 in the semiconductor substrate 41. The signal extracting portion 765-1 includes at least an N+ semiconductor region 771-1 which is an N-type semiconductor region and a P+ semiconductor region 773-1 which is a P-type semiconductor region. The signal extracting portion 765-2 includes at least an N+ semiconductor region 771-2 which is an N-type semiconductor region and a P+ semiconductor region 773-2 which is a P-type semiconductor region.

The pixel 10 includes a transfer transistor 721A, an FD 722A, a reset transistor 723A, an amplification transistor 724A, and a selection transistor 725A for the signal extracting portion 765-1.

Also, the pixel 10 includes a transfer transistor 721B, an FD 722B, a reset transistor 723B, an amplification transistor 724B, and a selection transistor 725B for the signal extracting portion 765-2.

The vertical drive portion 22 applies a predetermined voltage MIX0 (first voltage) to the P+ semiconductor region 773-1 and applies a predetermined voltage MIX1 (second voltage) to the P+ semiconductor region 773-2. For example, one of the Voltages MIX0 and MIX1 is 1.5 V, and the other is 0 V. The P+ semiconductor region 773-1 and 773-2 are voltage application portions to which the first voltage and the second voltage are applied.

The N+ semiconductor regions 771-1 and 771-2 are charge detecting portions that detect and accumulate charges generated by the light that is incident on the semiconductor substrate 41 being photoelectrically converted.

The transfer transistor 721A transfers the charges accumulated in the N+ semiconductor region 771-1 to the FD 722A by being brought into a conductive state in response to a transfer driving signal TRG supplied to the gate electrode being brought into an active state. The transfer transistor 721B transfers the charges accumulated in the N+ semiconductor region 771-2 to the FD 722B by being brought into a conductive state in response to a transfer driving signal TRG supplied to the gate electrode being brought into an active state.

The FD 722A temporarily holds the charges supplied from the N+ semiconductor region 771-1. The FD 722B temporarily holds the charges supplied from the N+ semiconductor region 771-2.

The reset transistor 723A resets the potential of the FD 722A to a predetermined level (reset voltage VDD) by being brought into a conductive state in response to a reset driving signal RST supplied to the gate electrode being brought into an active state. The reset transistor 723B resets the potential of the FD 722B to the predetermined level (reset voltage VDD) by being brought into a conductive state in response to a reset driving signal RST supplied to the gate electrode being brought into an active state. Note that when the reset transistors 723A and 723B are brought into an active state, the transfer transistors 721A and 721B are also brought into an active state at the same time.

The amplification transistor 724A configures a source follower circuit with a load MOS of the constant current source circuit portion 726A connected to one end of the vertical signal line 29A by the source electrode thereof being connected to the vertical signal line 29A via the selection transistor 725A. The amplification transistor 724B configures a source follower circuit with a load MOS of the constant current source circuit portion 726B connected to one end of the vertical signal line 29B by the source electrode thereof being connected to the vertical signal line 29B via the selection transistor 725B.

The selection transistor 725A is connected between the source electrode of the amplification transistor 724A and the vertical signal line 29A. The selection transistor 725A is brought into a conductive state in response to a selection driving signal SEL supplied to the gate electrode being brought into an active state and outputs a pixel signal output from the amplification transistor 724A to the vertical signal line 29A.

The selection transistor 725B is connected between the source electrode of the amplification transistor 724B and the vertical signal line 29B. The selection transistor 725B is brought into a conductive state in response to a selection driving signal SEL supplied to the gate electrode being brought into an active state and outputs a pixel signal output from the amplification transistor 724B to the vertical signal line 29B.

The transfer transistors 721A and 721B, the reset transistors 723A and 723B, the amplification transistors 724A and 724B, and the selection transistors 725A and 725B of the pixel 10 are controlled by, for example, the vertical drive portion 22.

FIG. 33 is a sectional view in a case where the pixel 10 is a CAPD pixel.

In FIG. 33, parts corresponding to those in the aforementioned other configuration examples are denoted by the same reference signs, and description of the parts will be appropriately omitted.

In the pixel 10 in the case where it is a CAPD pixel, the entire semiconductor substrate 41 formed of a P type, for example, is a photoelectric conversion region and is formed of the aforementioned SiGe region or Ge region. The surface of the semiconductor substrate 41 on which the on-chip lens 47 is formed is a light incidence surface, and the surface on the side opposite to the light incidence surface is a circuit formation surface.

An oxide film 764 is formed at a center part of the pixel 10 in the vicinity of the circuit formation surface of the semiconductor substrate 41, and the signal extracting portion 765-1 and the signal extracting portion 765-2 are formed at both ends of the oxide film 764, respectively.

The signal extracting portion 765-1 includes an N+ semiconductor region 771-1 and an N-semiconductor region 772-1 where the donor impurity concentration is lower than that in the N+ semiconductor region 771-1, which are N-type semiconductor regions, and a P+ semiconductor region 773-1 and a P- semiconductor region 774-1 where the acceptor impurity concentration is lower than that in the P+ semiconductor region 773-1, which are P-type semiconductor regions. The donor impurities include, for example, elements belonging to Group V in the periodic table of elements, such as phosphorus (P) and arsenic (As) with respect to Si, and acceptor impurities include, for example, elements belonging to Group III in the periodic table of elements, such as boron (B) with respect to Si. The elements that are donor impurities will be referred to as donor elements, and the elements that are acceptor impurities will be referred to as acceptor elements.

In the signal extracting portion 765-1, the N+ semiconductor region 771-1 and the N-semiconductor region 772-1 are annually formed to surround the circumference of the P+ semiconductor region 773-1 and the P- semiconductor region 774-1 around the P+ semiconductor region 773-1 and the P- semiconductor region 774-1 at the centers. The P+ semiconductor region 773-1 and the N+ semiconductor region 771-1 are in contact with the multilayer wiring layer 42. The P- semiconductor region 774-1 is disposed above the P+ semiconductor region 773-1 (on the side of the on-chip lens 47) to cover the P+ semiconductor region 773-1, and the N- semiconductor region 772-1 is disposed above the N+ semiconductor region 771-1 (on the side of the on-chip lens 47) to cover the N+ semiconductor region 771-1. In other words, the P+ semiconductor region 773-1 and the N+ semiconductor region 771-1 are disposed on the side of the multilayer wiring layer 42 inside the semiconductor substrate 41, and the N- semiconductor region 772-1 and the P- semiconductor region 774-1 are disposed on the side of the on-chip lens 47 inside the semiconductor substrate 41. Also, a separating portion 775-1 for separating the N+ semiconductor region 771-1 and the P+ semiconductor region 773-1 is formed of an oxide film or the like between the regions.

Similarly, the signal extracting portion 765-2 includes an N+ semiconductor region 771-2 and an N- semiconductor region 772-2 where donor impurity concentration is lower than that in the N+ semiconductor region 771-2, which are N-type semiconductor regions, a P+ semiconductor region 773-2 and a P- semiconductor region 774-2 where the acceptor impurity concentration is lower than that in the P+ semiconductor region 773-2, which are P-type semiconductor regions.

In the signal extracting portion 765-2, the N+ semiconductor region 771-2 and the N-semiconductor region 772-2 are annually formed to surround the circumference of the P+ semiconductor region 773-2 and the P- semiconductor region 774-2 around the P+ semiconductor region 773-2 and the P- semiconductor region 774-2 at the centers. The P+ semiconductor region 773-2 and the N+ semiconductor region 771-2 are in contact with the multilayer wiring layer 42. The P- semiconductor region 774-2 is disposed above the P+ semiconductor region 773-2 (on the side of the on-chip lens 47) to cover the P+ semiconductor region 773-2, and the N- semiconductor region 772-2 is disposed above the N+ semiconductor region 771-2 (on the side of the on-chip lens 47) to cover the N+ semiconductor region 771-2. In other words, the P+ semiconductor region 773-2 and the N+ semiconductor region 771-2 are disposed on the side of the multilayer wiring layer 42 inside the semiconductor substrate 41, and the N- semiconductor region 772-2 and the P- semiconductor region 774-2 are disposed on the side of the on-chip lens 47 inside the semiconductor substrate 41. Also, a separating portion 775-2 for separating the N+ semiconductor region 771-2 and the P+ semiconductor region 773-2 is formed of an oxide film or the like between the regions.

An oxide film 764 is also formed between the N+ semiconductor region 771-1 of the signal extracting portion 765-1 of the predetermined pixel 10 and the N+ semiconductor region 771-2 of the signal extracting portion 765-2 of the adjacent pixel 10, at the boundary region between the adjacent pixels 10.

A P+ semiconductor region 701 covering the entire light incidence surface is formed by laminating films with positive fixed charges at the interface of the semiconductor substrate 41 on the light incidence surface side.

Hereinafter, the signal extracting portions 765-1 and the signal extracting portions 765-2 will be simply referred to as signal extracting portions 765 as well in a case where it is not necessary to particularly distinguish them.

Also, the N+ semiconductor region 771-1 and the N+ semiconductor region 771-2 will be simply referred to as N+ semiconductor regions 771 as well in a case where it is not necessary to particularly distinguish them, and the N-semiconductor region 772-1 and the N-semiconductor region 772-2 will be simply referred to as N-semiconductor regions 772 as well in a case where it is not necessary to particularly distinguish them.

Moreover, the P+ semiconductor region 773-1 and the P+ semiconductor region 773-2 will be simply referred to as P+ semiconductor regions 773 as well in a case where it is not necessary to particularly distinguish them, and the P- semiconductor region 774-1 and the P- semiconductor region 774-2 will be simply referred to as P- semiconductor regions 774 as well in a case where it is not necessary to particularly distinguish them. Also, the separating portion 775-1 and the separating portion 775-2 will be simply referred to as separating portions 775 as well in a case where it is not necessary to particularly distinguish them.

The N+ semiconductor region 771 provided in the semiconductor substrate 41 functions as a charge detecting portion for detecting the amount of light that is incident on the pixel 10 form the outside, that is, the amount of signal charges generated through photoelectric conversion performed by the semiconductor substrate 41. Note that it is also possible to regard the N+ semiconductor region 771 including the N- semiconductor region 772 with low donor impurity concentration as the charge detecting portion. Also, the P+ semiconductor region 773 functions as a voltage application portion for implanting multiple carrier currents in the semiconductor substrate 41, that is, for applying a voltage directly to the semiconductor substrate 41 and generating an electric field inside the semiconductor substrate 41. Note that it is also possible to regard the P+ semiconductor region 773 including the P- semiconductor region 774 with low acceptor impurity concentration as a voltage application portion.

Diffusion films 811 regularly disposed at predetermined intervals, for example, are formed at the interface of the semiconductor substrate 41 on the front surface side, which is the side where the multilayer wiring layer 42 is formed. Also, an insulating film (gate insulating film) is formed between the diffusion films 811 and the interface of the semiconductor substrate 41 although illustration is omitted.

The diffusion films 811 are regularly disposed at predetermined intervals, for example, at the interface of the semiconductor substrate 41 on the front surface side, which is the side where the multilayer wiring layer 42 is formed, and prevents light passing from the semiconductor substrate 41 to the multilayer wiring layer 42, and light reflected by a reflecting member 815, which will be described later, from braking through to the outside of the semiconductor substrate 41 (the side of the on-chip lens 47) by being diffused by the diffusion films 811. The material of the diffusion films 811 may be any material as long as it contains polycrystalline silicon, such as polysilicon, as a main component.

Note that the diffusion films 811 are formed while avoiding the positions of the N+ semiconductor region 771-1 and the P+ semiconductor region 773-1 such that the diffusion films 811 do not overlap the positions of the N+ semiconductor region 771-1 and the P+ semiconductor region 773-1.

In FIG. 33, the first metal film M1 that is the closest to the semiconductor substrate 41 from among the four layers, namely the first metal film M1 to the fourth metal film M4 in the multilayer wiring layer 42, includes a power source line 813 for supplying a power source voltage, a voltage application wiring 814 for applying a predetermined voltage to the P+ semiconductor region 773-1 or 773-2, and a reflecting member 815 which is a member that reflects incident light. The voltage application wiring 814 is connected to the P+ semiconductor region 773-1 or 773-2 via the contact electrode 812, a predetermined voltage MIX0 is applied to the P+ semiconductor region 773-1, and a predetermined voltage MIX1 is applied to the P+ semiconductor region 773-2.

Although wirings other than the power source line 813 and the voltage application wiring 814 serve as the reflecting member 815 in the first metal film M1 in FIG. 33, some of reference signs are omitted to prevent the drawing from becoming complicated. The reflecting member 815 is a dummy wiring provided for the purpose of reflecting incident light. The reflecting member 815 is disposed below the N+ semiconductor regions 771-1 and 771-2 such that the reflecting member 815 overlaps the N+ semiconductor regions 771-1 and 771-2, which are charge detecting portion, in a plan view. Also, a contact electrode (not illustrated) that connects the N+ semiconductor region 771 to the transfer transistor 721 is formed in the first metal film M1 to transfer the charges accumulated in the N+ semiconductor region 771 to the FD 722.

Note that although the reflecting member 815 is disposed in the same layer of the first metal film M1 in this example, the present invention is not necessarily limited to the configuration in which the reflecting member 815 is disposed in the same layer.

In the second metal film M2 which is located in the second layer from the side of the semiconductor substrate 41, the voltage application wiring 816 connected to the voltage application wiring 814 in the first metal film M1, a control line 817 that transmits the transfer driving signal TRG, the reset driving signal RST, the selection driving signal SEL, the FD driving signal FDG, and the like, a ground line, and the like are formed, for example. Also, the FD 722 and the like are also formed in the second metal film M2.

In the third metal film M3 in the third layer from the side of the semiconductor substrate 41, the vertical signal line 29, the shielding wiring, and the like are formed, for example.

In the fourth metal film M4 in the fourth layer from the side of the semiconductor substrate 41, a voltage supply line (not illustrated) for applying a predetermined voltage MIX0 or MIX1 is formed in the P+ semiconductor regions 773-1 and 773-2 which are voltage application portions of the signal extracting portion 65, for example.

Operations of the pixel 10 in FIG. 33, which is a CAPD pixel, will be described.

The vertical drive portion 22 drives the pixel 10 and sorts the signals in accordance with the charges obtained through photoelectric conversion to the FD 722A and 722B (FIG. 32).

The vertical drive portion 22 applies a voltage to the two P+ semiconductor regions 773 via the contact electrode 812 and the like. For example, the vertical drive portion 22 applies a voltage of 1.5 V to the P+ semiconductor region 773-1 and applies a voltage of 0 V to the P+ semiconductor region 773-2.

Through the application of the voltage, an electric field is generated between the two P+ semiconductor regions 773 in the semiconductor substrate 41, and a current flows from the P+ semiconductor region 773-1 to the P+ semiconductor region 773-2. In this case, holes inside the semiconductor substrate 41 move in the direction to the P+ semiconductor region 773-2, and electrons move in the direction to the P+ semiconductor region 773-1.

Therefore, if infrared light (reflected light) from the outside is incident on the inside of the semiconductor substrate 41 via the on-chip lens 47 in this state, and the infrared light is photoelectrically converted inside the semiconductor substrate 41 and is converted into pairs of electrons and holes, the thus obtained electrons are guided in the direction to the P+ semiconductor region 773-1 by the electric field between the P+ semiconductor regions 773 and then moves to the inside of the N+ semiconductor region 771-1.

In this case, the electrons generated through the photoelectric conversion are used as signal charges for detecting a signal in accordance with the amount of infrared light that has been incident on the pixel 10, that is, the amount of received infrared light.

In this manner, charges in accordance with the electrons that have moved to the inside of the N+ semiconductor region 771-1 are accumulated in the N+ semiconductor region 771-1, and the charges are detected by the column processing portion 23 via the FD 722A, the amplification transistor 724A, the vertical signal line 29A, and the like.

In other words, the charges accumulated in the N+ semiconductor region 771-1 are transferred to the FD 722A that is connected directly to the N+ semiconductor region 771-1, and the signal in accordance with the charges transferred to the FD 722A is read by the column processing portion 23 via the amplification transistor 724A and the vertical signal line 29A. Then, processing such as AD conversion processing is performed on the read signal by the column processing portion 23, and a pixel signal obtained as a result is supplied to the signal processing portion 26.

The pixel signal is a signal indicating the amount of charges in accordance with the electrons detected by the N+ semiconductor region 771-1, that is, the amount of charges accumulated in the FD 722A. In other words, it is also possible to state that the pixel signal is a signal indicating the amount of infrared light received by the pixel 10.

Note that at this time, a pixel signal in accordance with electrons detected in the N+ semiconductor region 771-2 may also appropriately be used for distance measurement similarly to the case of the N+ semiconductor region 771-1.

Also, a voltage is applied to the two P+ semiconductor regions 73 via a contact by the vertical drive portion 22 such that an electric field in a direction opposite to that of the electric field generated inside the semiconductor substrate 41 until then is generated at the following timing. Specifically, a voltage of 1.5 V is applied to the P+ semiconductor region 773-2, and a voltage of 0 V is applied to the P+ semiconductor region 773-1.

In this manner, an electric field is generated between the two P+ semiconductor regions 773 in the semiconductor substrate 41, and a current flows from the P+ semiconductor region 773-2 to the P+ semiconductor region 773-1.

If infrared light (reflected light) is incident from the outside to the inside of the semiconductor substrate 41 via the on-chip lens 47 in this state, and the infrared light is photoelectrically converted into pairs of electrons and holes inside the semiconductor substrate 41, then the obtained electrons are guided in the direction to the P+ semiconductor region 773-2 by the electric field between the P+ semiconductor regions 773 and move to the inside of the N+ semiconductor region 771-2.

In this manner, charges in accordance with the electrons that have moved to the inside of the N+ semiconductor region 771-2 are accumulated in the N+ semiconductor region 771-2, and the charges are detected by the column processing portion 23 via the FD 722B, the amplification transistor 724B, the vertical signal line 29B, and the like.

In other words, the charges accumulated in the N+ semiconductor region 771-2 are transferred to the FD 722B that is connected directly to the N+ semiconductor region 771-2, and the signal in accordance with the charges transferred to the FD 722B is read by the column processing portion 23 via the amplification transistor 724B and the vertical signal line 29B. Then, processing such as AD conversion processing is performed on the read signal by the column processing portion 23, and a pixel signal obtained as a result is supplied to the signal processing portion 26.

Note that at this time, a pixel signal in accordance with electrons detected in the N+ semiconductor region 771-1 may also appropriately be used for distance measurement similarly to the case of the N+ semiconductor region 771-2.

If pixel signals obtained through the photoelectric conversion in mutually different periods are obtained by the same pixels 10 in this manner, then the signal processing portion 26 can calculate the distance to the object on the basis of the pixel signals.

It is possible to enhance quantum efficiency of near-infrared light and to improve sensor sensitivity by forming the semiconductor substrate 41 by the SiGe region or the Ge region in the pixel 10 as a CAPD pixel configured as described above.

### 21. Configuration Example of Distance Measurement Module

FIG. 34 is a block diagram illustrating a configuration example of a distance measurement module that outputs distance measurement information using the above-described light receiving element 1.

A distance measurement module 500 includes a light emitting portion 511, a light emission control portion 512, and a light receiving portion 513.

The light emitting portion 511 includes a light source that emits light having a predetermined wavelength, and irradiates an object with irradiation light with brightness of which varies periodically. For example, the light emitting portion 511 includes a light emission diode that emits infrared light with a wavelength of equal to or greater than 780 nm as a light source and generates irradiation light in synchronization with a light emission control signal CLKp of a rectangular wave supplied from the light emission control portion 512.

Note that the light emission control signal CLKp is not limited to a rectangular wave as long as it is a period signal. For example, the light emission control signal CLKp may be a sine wave.

The light emission control portion 512 supplies the light emission control signal CLKp to the light emitting portion 511 and the light receiving portion 513 and controls a radiation timing of radiation light. The frequency of the light emission control signal CLKp is, for example, 20 megahertz (MHz). Note that the frequency of the light emission control signal CLKp is not limited to 20 megahertz and may be 5 megahertz, 100 megahertz, or the like.

The light receiving portion 513 receives reflected light reflected from an object, calculates distance information for each pixel in accordance with a result of light reception, and generates and outputs a depth image in which a depth value corresponding to a distance to the object (subject) is stored as a pixel value.

The light receiving element 1 having the aforementioned pixel structure of the indirect ToF scheme (the gate scheme or the CAPD scheme) or the light receiving element 1 having the pixel structure of the SPDAD pixels is used in the light receiving portion 513. For example, the light receiving element 1 as the light receiving portion 513 calculates distance information for each pixel from a pixel signal corresponding to charge distributed to the floating diffusion regions FD1 or FD2 of the pixels 10 of the pixel array portion 21 on the basis of the light emission control signal CLKp.

As described above, it is possible to incorporate the light receiving element 1 having the aforementioned pixel structure of the indirect ToF scheme or pixel structure of the direct ToF scheme as the light receiving portion 513 of the distance measurement module 500 that obtains and outputs information on the distance to the object. It is thus possible to improve sensor sensitivity and to improve the distance measurement property of the distance measurement module 500.

### 22. Configuration Example of Electronic Device

Note that, as described above, the light receiving element 1 can be applied to a distance measurement module, and can also be applied to various electronic devices such as, for example, imaging devices such as digital still cameras and digital video cameras equipped with a distance measurement function, and smartphones equipped with a distance measurement function.

FIG. 35 is a block diagram illustrating a configuration example of a smartphone as an electronic device to which the present technology is applied.

As illustrated in FIG. 35, a smartphone 601 is configured such that a distance measurement module 602, an imaging device 603, a display 604, a speaker 605, a microphone 606, a communication module 607, a sensor unit 608, a touch panel 609, and a control unit 610 are connected to each other via a bus 611. Further, the control unit 610 has functions as an application processing portion 621 and an operation system processing portion 622 by causing a CPU to execute a program.

The distance measurement module 500 illustrated in FIG. 34 is applied to the distance measurement module 602. For example, the distance measurement module 602 is disposed on the front surface of the smartphone 601, and can output a depth value of a surface shape of the face, hand, finger, or the like of a user of the smartphone 601 as a distance measurement result by performing distance measurement on a user of the smartphone 601.

The imaging device 603 is disposed on the front surface of the smartphone 601, and acquires an image capturing the user of the smartphone 601 by imaging the user as a subject. Note that although not illustrated in the drawing, a configuration in which the imaging device 603 is also disposed on the back surface of the smartphone 601 may be adopted.

The display 604 displays an operation screen for performing processing by the application processing portion 621 and the operation system processing portion 622, an image captured by the imaging device 603, and the like. The speaker 605 and the microphone 606 perform, for example, outputting of sound from a counterpart and collecting of user’s sound when making a call using the smartphone 601.

The communication module 607 performs network communication through a communication network such as the Internet, a public telephone network, a wide area communication network for wireless mobiles such as a so-called 4G line and 5G line, a wide area network (WAN), and a local area network (LAN), short-range wireless communication such as Bluetooth (registered trademark) and near field communication (NFC), and the like. The sensor unit 608 senses speed, acceleration, proximity, and the like, and the touch panel 609 acquires a user’s touch operation on the operation screen displayed on the display 604.

The application processing portion 621 performs processing for providing various services through the smartphone 601. For example, the application processing portion 621 can create a face by computer graphics that virtually reproduces the user’s facial expression on the basis of a depth value supplied from the distance measurement module 602, and can perform processing for displaying the face on the display 604. In addition, the application processing portion 621 can perform processing of creating, for example, three-dimensional shape data of an arbitrary three-dimensional object on the basis of a depth value supplied from the distance measurement module 602.

The operation system processing portion 622 performs processing for realizing basic functions and operations of the smartphone 601. For example, the operation system processing portion 622 can perform processing for authenticating a user’s face on the basis of a depth value supplied from the distance measurement module 602, and unlocking the smartphone 601. In addition, the operation system processing portion 622 can perform, for example, processing for recognizing a user’s gesture on the basis of a depth value supplied from the distance measurement module 602, and can perform processing for inputting various operations according to the gesture.

In the smartphone 601 configured in this manner, the above-described distance measurement module 500 is applied as the distance measurement module 602, and thus it is possible to perform, for example, processing for measuring and displaying a distance to a predetermined object or creating and displaying three-dimensional shape data of a predetermined object, and the like.

### 23. Example of Application to Moving Body

The technology according to the present disclosure (the present technology) can be applied to various products. For example, the technology according to the present disclosure may be realized as a device equipped in any type of moving body such as an automobile, an electric vehicle, a hybrid electric vehicle, a motorcycle, a bicycle, a personal mobility device, an airplane, a drone, a ship, and a robot.

FIG. 36 is a block diagram illustrating a schematic configuration example of a vehicle control system, which is an example of a moving body control system to which the technology according to the present disclosure can be applied.

The vehicle control system 12000 includes a plurality of electronic control units connected thereto via a communication network 12001. In the example illustrated in FIG. 36, the vehicle control system 12000 includes a drive system control unit 12010, a body system control unit 12020, an outside-vehicle information detection unit 12030, an inside-vehicle information detection unit 12040, and an integrated control unit 12050. In addition, as a functional configuration of the integrated control unit 12050, a microcomputer 12051, an audio/image output portion 12052, and an in-vehicle network interface (I/F) 12053 are shown.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The outside-vehicle information detection unit 12030 detects information on the outside of the vehicle having the vehicle control system 12000 mounted thereon. For example, an imaging portion 12031 is connected to the outside-vehicle information detection unit 12030. The outside-vehicle information detection unit 12030 causes the imaging portion 12031 to capture an image of the outside of the vehicle and receives the captured image. The outside-vehicle information detection unit 12030 may perform object detection processing or distance detection processing for peoples, cars, obstacles, signs, and letters on the road on the basis of the received image.

The imaging portion 12031 is an optical sensor that receives light and outputs an electrical signal according to the amount of the received light. The imaging portion 12031 can also output the electrical signal as an image or distance measurement information. In addition, the light received by the imaging portion 12031 may be visible light or invisible light such as infrared light.

The inside-vehicle information detection unit 12040 detects information on the inside of the vehicle. For example, a driver state detecting portion 12041 that detects a driver’s state is connected to the inside-vehicle information detection unit 12040. The driver state detecting portion 12041 includes, for example, a camera that captures an image of a driver, and the inside-vehicle information detection unit 12040 may calculate a degree of fatigue or concentration of the driver or may determine whether or not the driver is dozing on the basis of detection information input from the driver state detecting portion 12041.

The microcomputer 12051 can calculate a control target value of the driving force generation device, the steering mechanism, or the braking device on the basis of information acquired by the outside-vehicle information detection unit 12030 or the inside-vehicle information detection unit 12040 inside and outside the vehicle, and output a control command to the drive system control unit 12010. For example, the microcomputer 12051 can perform cooperative control for the purpose of implementing functions of an ADAS (advanced driver assistance system) including vehicle collision avoidance, impact mitigation, following traveling based on an inter-vehicle distance, vehicle speed maintenance traveling, vehicle collision warning, and vehicle lane deviation warning.

Further, the microcomputer 12051 can perform cooperative control for the purpose of automated driving or the like in which automated traveling is performed without depending on operations of the driver, by controlling the driving force generator, the steering mechanism, or the braking device and the like on the basis of information about the surroundings of the vehicle, the information being acquired by the outside-vehicle information detection unit 12030 or the inside-vehicle information detection unit 12040.

In addition, the microcomputer 12051 can output a control command to the body system control unit 12020 based on the information acquired by the outside-vehicle information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the outside-vehicle information detection unit 12030.

The sound image output portion 12052 transmits an output signal of at least one of sound and an image to an output device capable of visually or audibly notifying a passenger or the outside of the vehicle of information. In the example of FIG. 36, an audio speaker 12061, a display portion 12062, and an instrument panel 12063 are illustrated as examples of the output device. The display portion 12062 may include at least one of an on-board display and a head-up display, for example.

FIG. 37 is a diagram showing an example of an installation position of the imaging portion 12031.

In FIG. 37, a vehicle 12100 includes imaging portions 12101, 12102, 12103, 12104, and 12105 as the imaging portion 12031.

The imaging portions 12101, 12102, 12103, 12104, and 12105 are provided at positions such as a front nose, side-view mirrors, a rear bumper, a back door, and an upper portion of a windshield in a vehicle interior of the vehicle 12100, for example. The imaging portion 12101 provided on the front nose and the imaging portion 12105 provided in the upper portion of the windshield in the vehicle interior mainly acquire images of the front of the vehicle 12100. The imaging portions 12102 and 12103 provided on the side-view mirrors mainly acquire images of a lateral side of the vehicle 12100. The imaging portion 12104 provided on the rear bumper or the back door mainly acquires images of the rear of the vehicle 12100. Front view images acquired by the imaging portions 12101 and 12105 are mainly used for detection of preceding vehicles, pedestrians, obstacles, traffic lights, traffic signs, lanes, and the like.

FIG. 37 illustrates an example of imaging ranges of the imaging portions 12101 to 12104. An imaging range 12111 indicates an imaging range of the imaging portion 12101 provided at the front nose, imaging ranges 12112 and 12113 respectively indicate the imaging ranges of the imaging portions 12102 and 12103 provided at the side-view mirrors, and an imaging range 12114 indicates the imaging range of the imaging portion 12104 provided at the rear bumper or the back door. For example, by superimposing image data captured by the imaging portions 12101 to 12104, it is possible to obtain a bird’s-eye view image viewed from the upper side of the vehicle 12100.

At least one of the imaging portions 12101 to 12104 may have a function for obtaining distance information. For example, at least one of the imaging portions 12101 to 12104 may be a stereo camera constituted by a plurality of imaging elements or may be an imaging element that has pixels for phase difference detection.

For example, the microcomputer 12051 can extract, particularly, a closest three-dimensional object on a path through which the vehicle 12100 is traveling, which is a three-dimensional object traveling at a predetermined speed (for example, 0 km/h or higher) in the substantially same direction as the vehicle 12100, as a preceding vehicle by acquiring a distance to each three-dimensional object in the imaging ranges 12111 to 12114 and temporal change in the distance (a relative speed with respect to the vehicle 12100) on the basis of distance information obtained from the imaging portions 12101 to 12104. Furthermore, the microcomputer 12051 can set an inter-vehicle distance to be secured in advance in front of a preceding vehicle and can perform automated brake control (also including following stop control) or automated acceleration control (also including following start control). This can perform cooperative control for the purpose of, for example, automated driving in which the vehicle automatically travels without the need for driver’s operations.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging portions 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display portion 12062, forced deceleration or avoidance steering is performed through the drive system control unit 12010, and thus it is possible to perform driving support for collision avoidance.

At least one of the imaging portions 12101 to 12104 may be an infrared camera that detects infrared rays. For example, the microcomputer 12051 can recognize a pedestrian by determining whether there is a pedestrian in the captured image of the imaging portions 12101 to 12104. Such pedestrian recognition is performed by, for example, a procedure in which feature points in the captured images of the imaging portions 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging portions 12101 to 12104 and the pedestrian is recognized, the audio/image output portion 12052 controls the display portion 12062 so that a square contour line for emphasis is superimposed and displayed with the recognized pedestrian. In addition, the audio/image output portion 12052 may control the display portion 12062 so that an icon indicating a pedestrian or the like is displayed at a desired position.

An example of the vehicle control system to which the technology according to the present disclosure can be applied has been described above. The technology according to the present disclosure can be applied to the outside-vehicle information detection unit 12030 and the imaging portion 12031 among the above-described components. Specifically, the light receiving element 1 or the distance measurement module 500 can be applied to a distance detection processing block of the outside-vehicle information detection unit 12030 and the imaging portion 12031. By applying the technology according to the present disclosure to the outside-vehicle information detection unit 12030 and the imaging portion 12031, it is possible to measure a distance to an object such as a person, a vehicle, an obstacle, a sign, or a character on a road surface with high accuracy, and it is possible to reduce a driver’s fatigue of and improve the safety level of a driver and a vehicle by using obtained distance information.

The embodiments of the present technology are not limited to the aforementioned embodiments, and various changes can be made without departing from the gist of the present technology.

Further, in the above-described light receiving element 1, an example in which electrons are used as signal carriers has been described, but holes generated by photoelectric conversion may be used as signal carriers.

For example, it is possible to employ a mode in which all or some of the embodiments are combined for the aforementioned light receiving element 1.

The advantageous effects described in the present specification are merely exemplary and are not limited, and other advantageous effects of the advantageous effects described in the present specification may be achieved.

The present technology can be configured as follows.

A light receiving element including: a pixel array region in which pixels including photoelectric conversion regions are aligned in a matrix shape, in which the photoelectric conversion region of each pixel on a first semiconductor substrate, on which the pixel array region is formed, is formed of an SiGe region or a Ge region.

The light receiving element according to (1), in which the photoelectric conversion region of each pixel on the first semiconductor substrate is formed of an SiGe region or a Ge region, and a region other than the photoelectric conversion region of each pixel on the first semiconductor substrate is formed of an Si region.

The light receiving element according to (1) or (2), in which the pixels include at least photodiodes that serve as the photoelectric conversion regions and transfer transistors that transfer charges generated by the photodiodes, and a region of each pixel on the first semiconductor substrate below a gate of the transfer transistor is also formed of the SiGe region or the Ge region.

The light receiving element according to any one of (1) to (3), in which the entire pixel array region on the first semiconductor substrate is formed of the SiGe region or the Ge region.

The light receiving element according to (3) or (4), in which the pixels include at least photodiodes that serve as the photoelectric conversion regions, transfer transistors that transfer charges generated by the photodiodes, and charge holding portions that temporarily hold the charges, and the charge holding portions are formed of Si regions on the SiGe region or the Ge region.

The light receiving element according to any one of (1) to (5), in which Ge concentration in the SiGe region or the Ge region differs depending on a depth of the first semiconductor substrate

The light receiving element according to (6), in which Ge concentration in the first semiconductor substrate on a light incidence surface side is higher than Ge concentration in a pixel transistor formation surface of the first semiconductor substrate.

The light receiving element according to any one of (1) to (7), in which the first semiconductor substrate includes the pixel array region and a logic circuit region including a control circuit for each pixel.

The light receiving element according to any one of (1) to (8) further including: a second semiconductor substrate on which a logic circuit region including a control circuit for each pixel is formed, in which the light receiving element is configured by the first semiconductor substrate and the second semiconductor substrate being laminated.

The light receiving element according to any one of (1) to (9), in which the light receiving element is an indirect ToF sensor of a gate scheme.

The light receiving element according to any one of (1) to (9), in which the light receiving element is an indirect ToF sensor of a CAPD scheme.

The light receiving element according to any one of (1) to (9), in which the light receiving element is a direct ToF sensor including SPAD in the pixels.

The light receiving element according to any one of (1) to (9), in which the light receiving element is an IR imaging sensor in which all the pixels are pixels that receive infrared light.

The light receiving element according to any one of (1) to (9), in which the light receiving element is an RGBIR imaging sensor including pixels that receive infrared light and pixels that receive RGB light.

A manufacturing method for a light receiving element including: forming at least a photoelectric conversion region of each pixel in a pixel array region on a semiconductor substrate as an SiGe region or a Ge region.

The manufacturing method for a light receiving element according to (15), in which the SiGe region or the Ge region is formed by implanting Ge ions in an Si region.

The manufacturing method for a light receiving element according to (15), in which the SiGe region or the Ge region is formed by epitaxial growth in a region, from which the Si region is removed, on the semiconductor substrate.

The manufacturing method for a light receiving element according to any one of (15) to (17), in which an Si layer that serves as a charge holding portion is formed on the SiGe region or the Ge region on the semiconductor substrate.

The manufacturing method for a light receiving element according to any one of (15) to (18), in which the light receiving element is formed such that Ge concentration in the SiGe region or the Ge region differs in accordance with a depth of the semiconductor substrate.

An electronic device including: a predetermined light emitting source; and a light receiving element that includes a pixel array region in which pixels including photoelectric conversion regions are aligned in a matrix shape, the photoelectric conversion region of each pixel on a first semiconductor substrate, on which the pixel array region is formed, is formed of an SiGe region or a Ge region.

### REFERENCE SIGNS LIST

1 Light receiving element
10 Pixel
PD Photodiode
TRG Transfer transistor
21 Pixel array portion
41 Semiconductor substrate (first substrate)
42 Multilayer wiring layer
50 P-type semiconductor region
52 N-type semiconductor region
111 Pixel array region
141 Semiconductor substrate (second substrate)
201 Pixel circuit
202 ADC (AD converter)
351 Oxide film
371 MIM capacitor element
381 First color filter layer
382 Second color filter layer
441 N well region
442 P-type diffusion layer
500 Distance measurement module
511 Light emitting portion
512 Light emission control portion
513 Light receiving portion
601 Smartphone
602 Distance measurement module

What is claimed is:

1. A light receiving element, comprising:
a pixel array region in which pixels including photoelectric conversion regions are aligned in a matrix shape,
wherein the photoelectric conversion region of each pixel on a first semiconductor substrate, on which the pixel array region is formed, is formed of an SiGe region or a Ge region.

2. The light receiving element according to claim 1, wherein the photoelectric conversion region of each pixel on the first semiconductor substrate is formed of an SiGe region or a Ge region, and a region other than the photoelectric conversion region of each pixel on the first semiconductor substrate is formed of an Si region.

3. The light receiving element according to claim 1,
wherein the pixels include at least photodiodes that serve as the photoelectric conversion regions and transfer transistors that transfer charges generated by the photodiodes, and
a region of each pixel on the first semiconductor substrate below a gate of the transfer transistor is also formed of the SiGe region or the Ge region.

4. The light receiving element according to claim 1, wherein the entire pixel array region on the first semiconductor substrate is formed of the SiGe region or the Ge region.

5. The light receiving element according to claim 3,
wherein the pixels include at least photodiodes that serve as the photoelectric conversion regions, transfer transistors that transfer charges generated by the photodiodes, and charge holding portions that temporarily hold the charges, and
the charge holding portions are formed of Si regions on the SiGe region or the Ge region.

6. The light receiving element according to claim 1, wherein Ge concentration in the SiGe region or the Ge region differs depending on a depth of the first semiconductor substrate.

7. The light receiving element according to claim 6, wherein Ge concentration in the first semiconductor substrate on a light incidence surface side is higher than Ge concentration in a pixel transistor formation surface of the first semiconductor substrate.

8. The light receiving element according to claim 1, wherein the first semiconductor substrate includes the pixel array region and a logic circuit region including a control circuit for each pixel.

9. The light receiving element according to claim 1, further comprising:
a second semiconductor substrate on which a logic circuit region including a control circuit for each pixel is formed,
wherein the light receiving element is configured by the first semiconductor substrate and the second semiconductor substrate being laminated.

10. The light receiving element according to claim 1, wherein the light receiving element is an indirect ToF sensor of a gate scheme.

11. The light receiving element according to claim 1, wherein the light receiving element is an indirect ToF sensor of a CAPD scheme.

12. The light receiving element according to claim 1, wherein the light receiving element is a direct ToF sensor including SPAD in the pixels.

13. The light receiving element according to claim 1, wherein the light receiving element is an IR imaging sensor in which all the pixels are pixels that receive infrared light.

14. The light receiving element according to claim 1, wherein the light receiving element is an RGBIR imaging sensor including pixels that receive infrared light and pixels that receive RGB light.

15. A manufacturing method for a light receiving element, comprising:
forming at least a photoelectric conversion region of each pixel in a pixel array region on a semiconductor substrate as an SiGe region or a Ge region.

16. The manufacturing method for a light receiving element according to claim 15, wherein the SiGe region or the Ge region is formed by implanting Ge ions in an Si region.

17. The manufacturing method for a light receiving element according to claim 15, wherein the SiGe region or the Ge region is formed by epitaxial growth in a region from which the Si region is removed on the semiconductor substrate.

18. The manufacturing method for a light receiving element according to claim 15, wherein an Si layer that serves as a charge holding portion is formed on the SiGe region or the Ge region on the semiconductor substrate.

19. The manufacturing method for a light receiving element according to claim 15, wherein the light receiving element is formed such that Ge concentration in the SiGe region or the Ge region differs in accordance with a depth of the semiconductor substrate.

20. An electronic device, comprising:
a light receiving element that includes a pixel array region in which pixels including photoelectric conversion regions are aligned in a matrix shape, wherein the photoelectric conversion region of each pixel on a first semiconductor substrate, on which the pixel array region is formed, is formed of an SiGe region or a Ge region.
